(19) United States
(12) Patent Application Publication
(10) Pub. No.: US 2025/0107352 A1
(43) Pub. Date: Mar. 27, 2025

(54) DISPLAY APPARATUS

(71) Applicant: SAMSUNG DISPLAY CO., LTD., YONGIN-SI, GYEONGGI-DO (KR)

(72) Inventors: Kwangsoo BAE, YONGIN-SI, GYEONGGI-DO (KR); Gunhee KIM, YONGIN-SI, GYEONGGI-DO (KR); Jungwoo PARK, YONGIN-SI, GYEONGGI-DO (KR); Bokwang SONG, YONGIN-SI, GYEONGGI-DO (KR)

(21) Appl. No.: 18/897,217

(22) Filed: Sep. 26, 2024

(30) Foreign Application Priority Data
Sep. 27, 2023 (KR) 10-2023-0131168

(51) Int. Cl. H10K 59/122; H10K 59/121; H10K 59/80

(52) U.S. Cl. CPC H10K 59/122; H10K 59/121; H10K 59/873; H10K 59/8792

(57) ABSTRACT

A display apparatus includes a pixel circuit layer disposed on a substrate and including a plurality of sub-pixel circuits, a planarization layer disposed on the pixel circuit layer, a first organic pattern disposed on the planarization layer, wherein the first organic pattern has a first slope surface inclined in a first direction, a second slope surface inclined in a second direction different from the first direction, and an upper surface connecting the first slope surface to the second slope surface, a first light-emitting diode including a first pixel electrode extending from an upper surface of the planarization layer to the upper surface of the first organic pattern along the first slope surface, and a second light-emitting diode including a second pixel electrode extending from the upper surface of the planarization layer to the upper surface of the first organic pattern along the second slope surface.

### CROSS-REFERENCE TO RELATED APPLICATION

This application is claims priority under 35 U.S.C. § 119 to Korean Patent Application No. 10-2023-0131168, filed on Sep. 27, 2023, in the Korean Intellectual Property Office, the disclosure of which is incorporated by reference herein in its entirety.

### 1. TECHNICAL FIELD

One or more embodiments of the inventive concept relate to a display apparatus.

### 2. DESCRIPTION OF THE RELATED ART

As display apparatuses have become thinner and more lightweight, and their range of use has gradually been extended, there is a growing demand for display apparatuses that can deliver high quality images. For example, a display apparatus is disposed inside a vehicle to provide images to a user sitting on a driver's seat or a passenger seat of the vehicle.

### SUMMARY

One or more embodiments include a multi-view display apparatus configured to display different images depending on a user's position.

According to one or more embodiments, a display apparatus includes a pixel circuit layer disposed on a substrate and including a plurality of sub-pixel circuits, a planarization layer disposed on the pixel circuit layer, a first organic pattern disposed on the planarization layer, wherein the first organic pattern has a first slope surface inclined in a first direction, a second slope surface inclined in a second direction different from the first direction, and an upper surface connecting the first slope surface to the second slope surface, a first light-emitting diode including a first pixel electrode extending from an upper surface of the planarization layer to the upper surface of the first organic pattern along the first slope surface, and a second light-emitting diode including a second pixel electrode extending from the upper surface of the planarization layer to the upper surface of the first organic pattern along the second slope surface.

The first light-emitting diode and the second light-emitting diode are configured to emit light of a same color.

The first light-emitting diode and the second light-emitting diode are configured to emit light according to different electrical signals from each other.

The display apparatus further includes a bank layer disposed on the planarization layer and defining openings that overlap with the first pixel electrode and the second pixel electrode respectively.

The display apparatus further includes: an encapsulation layer disposed on the first light-emitting diode and the second light-emitting diode; and a light-blocking layer disposed on the encapsulation layer and defining light-transmissive openings overlapping the openings of the bank layer in a plan view.

A first height in a thickness direction from the upper surface of the planarization layer to the upper surface of the first organic pattern is about 10 μm or less.

The first pixel electrode and the second pixel electrode are spaced apart from each other in a third direction parallel to an upper surface of the substrate, a width in the third direction of the first slope surface is less than a width in the third direction of the first pixel electrode, and a width in the third direction of the second slope surface is less than a width in the third direction of the second pixel electrode.

The display apparatus further includes a third light-emitting diode including a third pixel electrode disposed on the upper surface of the first organic pattern.

The first light-emitting diode, the second light-emitting diode, and the third light-emitting diode are configured to emit light of a same color as each other.

The first light-emitting diode, the second light-emitting diode, and the third light-emitting diode are configured to emit light according to different electrical signals from each other.

According to one or more embodiments, a display apparatus includes a pixel circuit layer disposed on a substrate and including a plurality of sub-pixel circuits, a planarization layer disposed on the pixel circuit layer, a first organic pattern disposed on the planarization layer, wherein the first organic pattern has a first slope surface inclined in a first direction, a second slope surface inclined in a second direction different from the first direction, and an upper surface connecting the first slope surface to the second slope surface, a second organic pattern which is disposed on the planarization layer, is spaced apart in a third direction from the first organic pattern, wherein the second organic pattern has a third inclined surface inclined in the first direction, a fourth slope surface inclined in the second direction, and an upper surface connecting the third slope surface to the fourth slope surface, a plurality of first sub-pixels overlapping the first organic pattern and configured to emit light of a first color, and a plurality of second sub-pixels overlapping the second organic pattern and configured to emit light of a second color different from the first color.

One of the plurality of first sub-pixels overlaps the first slope surface, another one of the plurality of first sub-pixels overlaps the second slope surface, one of the plurality of second sub-pixels overlaps the third slope surface, and another one of the plurality of second sub-pixels overlaps the fourth slope surface.

One of the plurality of first sub-pixels overlaps the upper surface of the first organic pattern, and one of the plurality of second sub-pixels overlaps the upper surface of the second organic pattern.

The plurality of first sub-pixels respectively include first light-emitting diodes, each including a first pixel electrode, an opposite electrode, and a first emission layer between the first pixel electrode and the opposite electrode, the plurality of second sub-pixels respectively include second light-emitting diodes, each including a second pixel electrode, the opposite electrode, and a second emission layer between the second pixel electrode and the opposite electrode, each of the first pixel electrodes extends from an upper surface of the planarization layer to the upper surface of the first organic pattern along the first slope surface or the second slope surface, and each of the second pixel electrodes extends from the upper surface of the planarization layer to the upper surface of the second organic pattern along the third slope surface or the fourth slope surface.

The display apparatus further includes a bank layer disposed on the planarization layer, wherein the bank layer defines openings that overlap with the first pixel electrodes and the second pixel electrodes respectively.

The display apparatus further including: an encapsulation layer disposed on the first light-emitting diodes and the second light-emitting diodes; and a light-blocking layer disposed on the encapsulation layer and defining light-transmissive openings overlapping the openings of the bank layer in a plan view.

A first height in a thickness direction from an upper surface of the planarization layer to the upper surface of the first organic pattern is different from a second height in the thickness direction from the upper surface of the planarization layer to the upper surface of the second organic pattern.

Each of a first height in a thickness direction from an upper surface of the planarization layer to the upper surface of the first organic pattern and a second height in the thickness direction from the upper surface of the planarization layer and the upper surface of the second organic pattern are 10 μm or less.

The display apparatus further includes: a third organic pattern spaced apart from the first organic pattern and the second organic pattern; and a plurality of third sub-pixels overlapping the third organic pattern and configured to emit light of a third color different from the first color and the second color.

The plurality of first sub-pixels are spaced apart from each other in a third direction parallel to an upper surface of the substrate, the first organic pattern extends in a fourth direction crossing the third direction, and the display apparatus further includes a plurality of third sub-pixels overlapping the first organic pattern and spaced apart in the fourth direction from the plurality of first sub-pixels.

### BRIEF DESCRIPTION OF THE DRAWINGS

FIG. 1 is a schematic perspective view of a display apparatus according to an embodiment of the inventive concept;

FIG. 2 is a schematic cross-sectional view of the display apparatus of FIG. 1, taken along line A-A′ of FIG. 1;

FIG. 3 is a schematic plan view of a display apparatus according to an embodiment of the inventive concept;

FIG. 4 is an equivalent circuit diagram of a sub-pixel of a display apparatus according to an embodiment of the inventive concept;

FIGS. 5 and 6 are enlarged plan views of a portion of a display apparatus according to one or more embodiments of the inventive concept;

FIG. 7 is a schematic cross-sectional view of the display apparatus of FIG. 5, taken along line C-C′ of FIG. 5;

FIG. 8 is a view for explaining a path of light emitted by a display apparatus according to an embodiment of the inventive concept;

FIG. 9 is a view for explaining a dual-view display apparatus according to an embodiment of the inventive concept;

FIG. 10 is a schematic enlarged plan view of a portion of a display apparatus according to an embodiment of the inventive concept;

FIG. 11 is a schematic cross-sectional view of a display apparatus of FIG. 10, taken along line D-D′ of FIG. 10;

FIG. 12 is a view for explaining a path of light emitted by a display apparatus according to an embodiment of the inventive concept;

FIG. 13 is a view for explaining a triple-view display apparatus according to an embodiment of the inventive concept; and

FIG. 14 is a schematic view of a vehicle including a display apparatus according to an embodiment of the inventive concept.

### DETAILED DESCRIPTION OF THE EXAMPLE EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

It will be understood that when a layer, region, or element is referred to as being “connected” to another layer, region, or element, it may be “directly connected” to the other layer, region, or element or may be “indirectly connected” to the other layer, region, or element with other layer, region, or element interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

In the present specification, “A and/or B” may mean A or B, or A and B. In the present specification, “at least one of A and B” may mean A or B, or A and B.

The x-axis, the y-axis and the z-axis are not limited to three axes of the rectangular coordinate system. For example, the x-axis, the y-axis, and the z-axis may be perpendicular to one another, or may represent different orientations that are not perpendicular to one another.

The term “about” or “approximately” used in this specification to refer to an arbitrary value may mean including values within a range generally accepted in the art due to measurement limitations or errors. For example, “about” may mean including values in a range of ±30%, 20%, 10%, or 5% of a value.

In the case where a certain embodiment may be implemented differently, a specific process may be performed in the order different from the described order. For example, two processes successively described may be simultaneously performed substantially and performed in the opposite order.

Sizes of elements in the drawings may be exaggerated or reduced for convenience of explanation. As an example, the size and thickness of each element shown in the drawings are represented for convenience of description, and thus, the disclosure is not necessarily limited thereto.

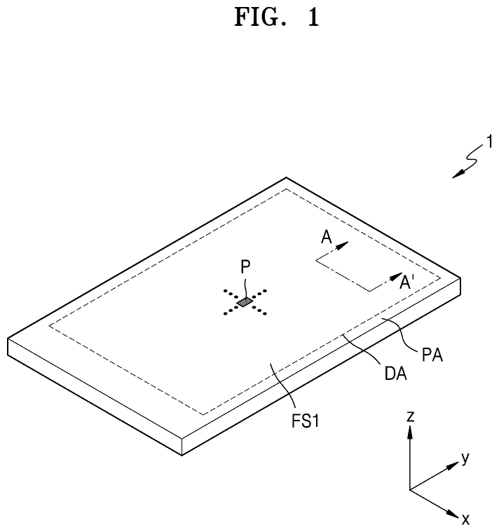

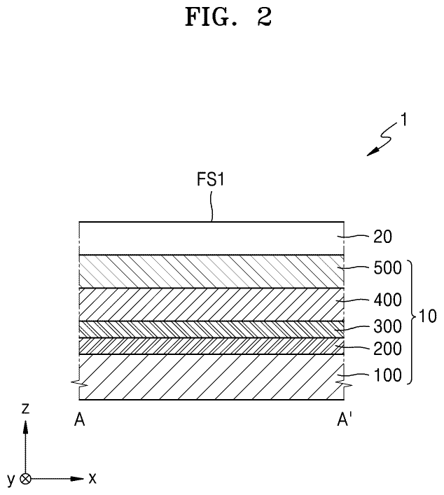

FIG. 1 is a schematic perspective view of a display apparatus 1 according to an embodiment of the inventive concept, and FIG. 2 is a schematic cross-sectional view of the display apparatus 1 of FIG. 1, taken along line A-A′ of FIG. 1.

Referring to FIG. 1, the display apparatus 1 according to an embodiment may include a display area DA and a peripheral area PA. The peripheral area PA may be arranged outside the display area DA and surround the display area DA. Various wirings and a driving circuit part configured to transfer electrical signals to the display area DA may be arranged in the peripheral area PA. The display apparatus 1 may be configured to display images by using light emitted from a plurality of sub-pixels P arranged in the display area DA.

Hereinafter, although the display apparatus is described using an organic light-emitting display apparatus as an example, the display apparatus according to an embodiment is not necessarily limited thereto. For example, the display apparatus 1 may be an organic light-emitting display, an inorganic light-emitting display, or a quantum-dot light-emitting display.

The display apparatus 1 may be implemented as various types of electronic apparatuses. In an embodiment, although the display apparatus 1 may be a display apparatus for a vehicle, the display apparatus according to an embodiment is not necessarily limited thereto.

As shown in FIG. 2, the display apparatus 1 may include a display panel 10 and a cover window 20. The display panel 10 may include a substrate 100, a pixel circuit layer 200, a display element layer 300, an encapsulation layer 400, and a light-blocking layer 500 sequentially stacked in a third direction (e.g., z direction or thickness direction).

The substrate 100 may include glass and/or polymer resin. For example, the substrate 100 may include a glass material including silicon oxide (SiOₓ) as a primary element, or a polymer resin including polyethersulfone, polyacrylate, polyetherimide, polyethylene naphthalate, polyethylene terephthalate, polyphenylene sulfide, polyimide, polycarbonate, cellulose tri acetate, and/or cellulose acetate propionate.

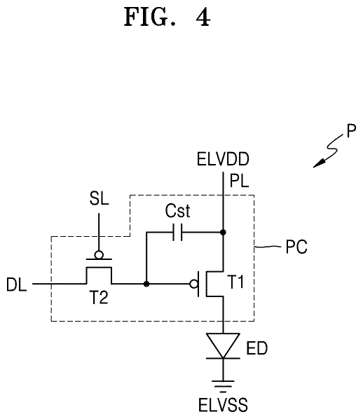

In conjunction with FIG. 2, the pixel circuit layer 200 may be disposed on the substrate 100. The pixel circuit layer 200 may include sub-pixel circuits PC (See FIG. 4), wirings, and insulating layers arranged in the display area DA. Some of the wirings and the insulating layers of the pixel circuit layer 200 may extend to the peripheral area PA.

The display element layer 300 may be disposed on the pixel circuit layer 200. The display element layer 300 may include display elements arranged in the display area DA. Each display element may be electrically connected to a corresponding sub-pixel circuit PC and form one sub-pixel with the corresponding sub-pixel circuit PC.

The encapsulation layer 400 may be disposed on the display element layer 300. The encapsulation layer 400 may encapsulate display elements located in the display element layer 300. In an embodiment, the encapsulation layer 400 may include at least one inorganic encapsulation layer and at least one organic encapsulation layer. For example, the inorganic encapsulation layer may include at least one inorganic material among aluminum oxide (Al₂O₃), titanium oxide (TiO₂), tantalum oxide (Ta₂O₅), zinc oxide (ZnOₓ, may be ZnO or ZnO₂), silicon oxide (SiOₓ), silicon nitride (SiNₓ), and/or silicon oxynitride (SiOₓN_{y}). For example, the organic encapsulation layer may include a polymer-based material such as an acrylic-based resin, an epoxy-based resin, polyimide, and polyethylene. In an embodiment, the organic encapsulation layer may include acrylate.

The light-blocking layer 500 may be disposed on the encapsulation layer 400. The light-blocking layer 500 may partially absorb light emitted by the display element layer 300 and limit a viewing angle of the display apparatus 1. For example, the light-blocking layer 500 may be configured to selectively transmit only a portion of light and block the rest of light depending on an angle formed by light emitted by the display element layer 300 and a third direction (z direction) perpendicular to a front surface FS1 of the display apparatus 1. The light-blocking layer 500 may be arranged in the display area DA. The light-blocking layer 500 may include a transmissive area which transmits light emitted by the display element layer 300.

The cover window 20 may be disposed on the display panel 10. In an embodiment, the cover window 20 may be attached to an element below the cover window 20, such as the light-blocking layer 500, using optically clear adhesive. The cover window 20 may be configured to protect the display panel 10. The cover window 20 may include at least one of glass, sapphire, and/or plastic. For example, the cover window 20 may be ultra-thin glass or colorless polyimide.

In some embodiments, a touch sensor layer may be further disposed between the encapsulation layer 400 and the light-blocking layer 500, or between the light-blocking layer 500 and the cover window 20. The touch sensor layer is a layer configured to sense a user's touch input using at least one of various touch methods such as a resistance method, a capacitance method, and the like.

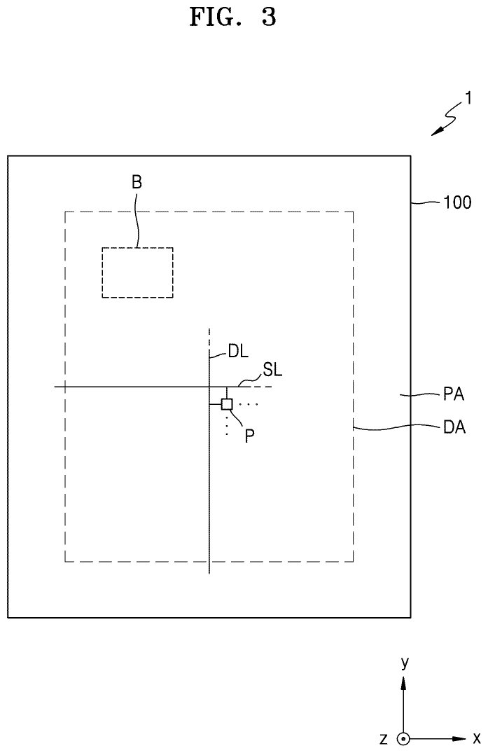

FIG. 3 is a schematic plan view of the display apparatus 1 according to an embodiment of the inventive concept.

Referring to FIG. 3, the display apparatus 1 may include the display area DA and the peripheral area PA. Because various kinds of elements forming the display apparatus 1 are disposed on the substrate 100, it may be understood that the substrate 100 includes the display area DA and the peripheral area PA. The display apparatus 1 may be configured to display images by using light emitted from a plurality of sub-pixels P arranged in the display area DA.

Each sub-pixel P may include a display element and a sub-pixel circuit PC (See FIG. 4) electrically connected to the display element. The display element may be an organic light-emitting diode (OLED) or an inorganic light-emitting diode. The display element may be configured to emit, for example, red, green, blue, or white light. The sub-pixel circuit of each sub-pixel P may include thin-film transistors and a storage capacitor. The sub-pixel circuit PC may be connected to a scan line SL and a data line DL crossing the scan line SL. In an embodiment, the scan line SL may extend in a first direction (x direction) and the data line DL may extend in a second direction (y direction).

The display element of each sub-pixel P may be configured to emit light by driving of the sub-pixel circuit PC. For example, the display area DA may display preset images by using lights emitted from the sub-pixels P. In the present specification, a pixel may denote a minimum unit set of sub-pixels P configured to emit one of red, green, blue, and white light. For example, a pixel may include a red sub-pixel, a green sub-pixel, and a blue sub-pixel. In some embodiments, the pixel may include a red sub-pixel, a green sub-pixel, a blue sub-pixel, and a white sub-pixel.

The peripheral area PA is a region in which sub-pixels P are not arranged and may be a non-display area that does not display images. A printed circuit board, a terminal part, and the like may be arranged in the peripheral area PA. The printed circuit board includes a built-in driving circuit part, a power supply line, and a driving circuit part configured to drive the sub-pixels P, and a driver integrated circuit (IC) is connected to the terminal part.

FIG. 4 is an equivalent circuit diagram of a sub-pixel of a display apparatus according to an embodiment of the inventive concept.

Referring to FIG. 4, a sub-pixel P may include a light-emitting diode ED as a display element, and a sub-pixel circuit PC connected to the light-emitting diode ED. The sub-pixel circuit PC may include a first thin-film transistor T1, a second thin-film transistor T2, and a storage capacitor Cst. The light-emitting diode ED may be configured to emit, for example, red, green, and blue light, or emit red, green, blue, and white light.

The second thin-film transistor T2, also referred to as a switching thin-film transistor, may be connected to the scan line SL and the data line DL. The second thin-film transistor T2 may be configured to transfer a data voltage from the data line DL to the first thin-film transistor T1 in accordance with a switching voltage received from the scan line SL. The storage capacitor Cst may be connected to the second thin-film transistor T2 and a driving voltage line PL. The storage capacitor Cst is configured to store a voltage corresponding to a difference between a data voltage transferred from the second thin-film transistor T2 and a first power voltage ELVDD supplied to the driving voltage line PL.

The first thin-film transistor T1, also referred to as a driving thin-film transistor, may be connected to the driving voltage line PL and the storage capacitor Cst. The first thin-film transistor T1 may be configured to control a driving current flowing through an organic light-emitting diode ED, in accordance with the voltage stored in the storage capacitor Cst. The light-emitting diode ED may be configured to emit light having a preset brightness corresponding to the driving current. An opposite electrode (e.g., a cathode) of the light-emitting diode ED may be configured to receive a second power voltage ELVSS.

Although it is described with reference to FIG. 4 that the sub-pixel circuit PC includes two transistors and one capacitor, the embodiment is not necessarily limited thereto. The number of thin-film transistors and the number of capacitors may vary depending on the design of the sub-pixel circuit PC.

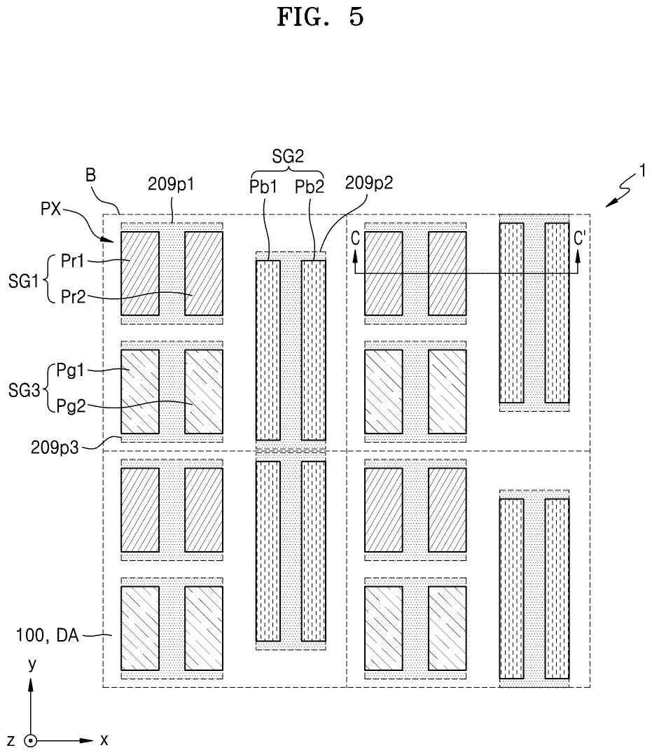

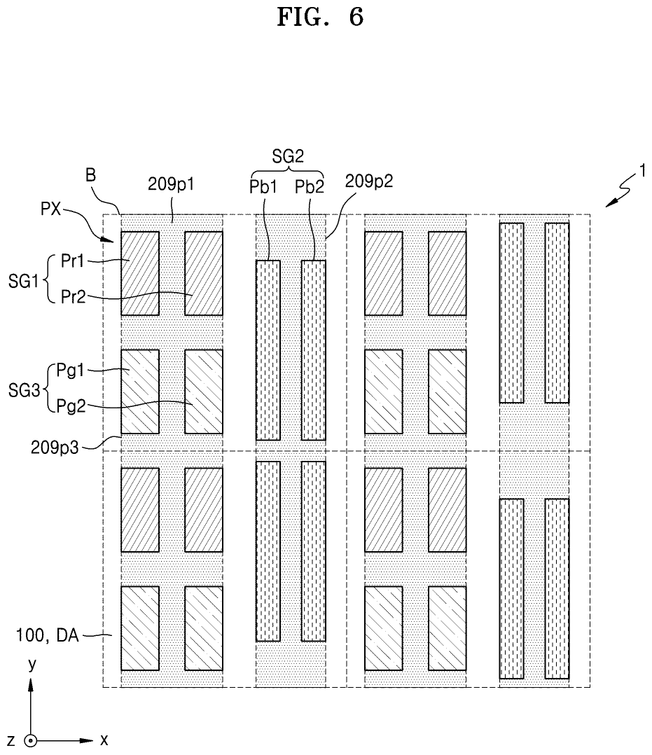

FIGS. 5 and 6 are enlarged plan views of a portion of a display apparatus according to one or more embodiments of the inventive concept. FIGS. 5 and 6 schematically show a region B of the display apparatus 1 shown in FIG. 3.

Referring to FIG. 5, the display apparatus 1 may include the substrate 100 (See FIG. 3). As described with reference to FIG. 1, the display apparatus 1 may include the display area DA and the peripheral area PA (e.g., see FIG. 3) outside the display area DA. For example, the peripheral area PA at least partially surround the display area DA.

A plurality of pixels PX may be arranged in the display area DA. For example, the pixels PX may form an array in the first direction (x direction) and the second direction (y direction) in the display area DA. Each pixel PX may include sub-pixels P (e.g., see FIG. 3) configured to emit one of red, green, blue, and white light. For example, it is shown in FIG. 5 that a pixel PX includes two red sub-pixels Pr1 and Pr2, two green sub-pixels Pg1 and Pg2, and two blue sub-pixels Pb1 and Pb2. In an embodiment, a pixel PX may further include two white sub-pixels. The red sub-pixels Pr1 and Pr2, the green sub-pixels Pg1 and Pg2, and blue sub-pixels Pb1 and Pb2 shown in FIG. 5 respectively represent emission areas of the light-emitting diodes ED (See FIG. 4).

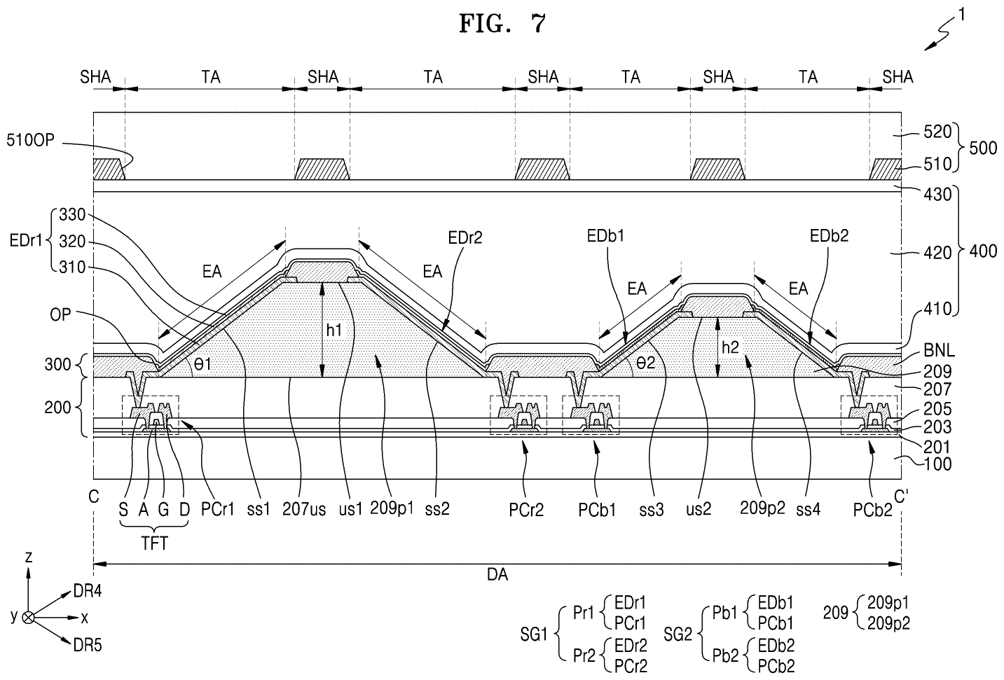

A plurality of organic patterns may be disposed on the substrate 100. The organic patterns may include organic insulating materials such as polyimide, polyamide, acrylic-based resin, benzocyclobutene, hexamethyldisiloxane (HMDSO), and/or phenolic-base resin. Each organic pattern may have two slope surfaces ss1, ss2, ss3, and ss4 inclined in two different directions and an upper surface us1 and us2 disposed between the two slope surfaces ss1, ss2, ss3, and ss4. (See FIG. 7). The slope surfaces ss1, ss2, ss3, and ss4 and upper surface us1 and us2 of the organic pattern may have a rectangular shape in which a length in the second direction (y direction) is greater than a length in the first direction (x direction), The slope surfaces ss1, ss2, ss3, and ss4 spaced apart from each other in the first direction (x direction) may be connected to each other by the upper surface us1 and us2.

An organic pattern may overlap a sub-pixel group SG1, SG2 and SG3 including sub-pixels P configured to emit light of the same color. The sub-pixels disposed on one organic pattern may be configured to emit light of the same color.

For example, a first organic pattern 209p1 may overlap a first sub-pixel group SG1 including a first red sub-pixel Pr1 and a second red sub-pixel Pr2 configured to emit red light, a second organic pattern 209p2 may overlap a second sub-pixel group SG2 including a first blue sub-pixel Pb1 and a second blue sub-pixel Pb2 configured to emit blue light, and a third organic pattern 209p3 may overlap a third sub-pixel group SG3 including a first green sub-pixel Pg1 and a second green sub-pixel Pg2 configured to emit green light.

Sub-pixels P in each sub-pixel group SG1, SG2 and SG3 may be spaced apart from each other in the first direction (x direction). For example, the first red sub-pixel Pr1 and the second red sub-pixel Pr2 in the first sub-pixel group SG1 may be apart from each other in the first direction (the x direction), the first blue sub-pixel Pb1 and the second blue sub-pixel Pb2 in the second sub-pixel group SG2 may be apart from each other in the first direction (the x direction), and the first green sub-pixel Pg1 and the second green sub-pixel Pg2 in the third sub-pixel group SG3 may be apart from each other in the first direction (the x direction).

The first organic pattern 209p1 and the second organic pattern 209p2 may be apart from each other in the first direction (the x direction). The first organic pattern 209p1 and the third organic pattern 209p3 may be apart from each other in the second direction (the y direction). The first organic pattern 209p1 and the third organic pattern 209p3 may be alternately arranged in the second direction (the y direction). The third organic pattern 209p3 and the second organic pattern 209p2 may be apart from each other in the first direction (the x direction).

The first sub-pixel group SG1 and the second sub-pixel group SG2 may be apart from each other in the first direction (the x direction). The first sub-pixel group SG1 and the third sub-pixel group SG3 may be apart from each other in the second direction (the y direction). The first sub-pixel group SG1 and the third sub-pixel group SG3 may be alternately arranged in the second direction (the y direction). The third sub-pixel group SG3 and the second sub-pixel group SG2 may be apart from each other in the first direction (the x direction). That is, the first red sub-pixel Pr1 and the first green sub-pixel Pg1 may be apart from each other in the second direction (the y direction), and the second red sub-pixel Pr2 and the second green sub-pixel Pg2 may be apart from each other in the second direction (the y direction). The first blue sub-pixel Pb1 may be apart from the second red sub-pixel Pr2 and the second green sub-pixel Pg2 in the first direction (the x direction).

One of sub-pixels P included in each sub-pixel group SG1, SG2 and SG3 may overlap a slope surface ss1, ss2, ss3, and ss4 on one side of the organic patterns, and another sub-pixel P of sub-pixels P included in each sub-pixel group SG1, SG2 and SG3 may overlap a slope surface ss1, ss2, ss3, and ss4 on another side of the organic patterns. For example, the first red sub-pixel Pr1, the first blue sub-pixel Pb1, and the first green sub-pixel Pg1 may respectively overlap a boundary surface on a left side (−x direction) (i.e., a side in the −x direction) of the first organic pattern 209p1, the second organic pattern 209p2, and the third organic pattern 209p3. The second red sub-pixel Pr2, the second blue sub-pixel Pb2, and the second green sub-pixel Pg2 may respectively overlap a boundary surface on a right side (+x direction) (i.e., a side in the +x direction) of the first organic pattern 209p1, the second organic pattern 209p2, and the third organic pattern 209p3.

Sub-pixels P arranged on the boundary surfaces on the left side (−x direction) of the organic patterns. For example, the first red sub-pixel Pr1, the first blue sub-pixel Pb1, and the first green sub-pixel Pg1 may be viewed by a user situated diagonally on the left side (−x direction) with respect to the third direction (z direction). Sub-pixels P arranged on the boundary surfaces on the right side (+x direction) of the organic patterns. For example, the second red sub-pixel Pr2, the second blue sub-pixel Pb2, and the second green sub-pixel Pg2 may be viewed by a user situated diagonally on the right side (+x direction) with respect to the third direction (z direction). For example, the third direction (z direction) is perpendicular to the upper surface of the substrate 100. Accordingly, the display apparatus 1 may be configured to display different images depending on a user's position.

Referring to FIG. 6, an organic pattern may extend in the second direction (y direction) and overlap the pixels PX arranged in the same column. For example, each of the first organic pattern 209p1 and the second organic pattern 209p2 may extend in the second direction (y direction) to overlap one or more pixels PX. The first organic pattern 209p1 and the second organic pattern 209p2 may be spaced apart from each other in the first direction (x direction).

The first organic pattern 209p1 may overlap one or more sub-pixel groups SG1 and SG3. For example, the first sub-pixel group SG1 and the third sub-pixel group SG3 may overlap the first organic pattern 209p1. The first sub-pixel group SG1 and the third sub-pixel group SG3 may be apart from each other in the second direction (y direction) and be alternately arranged.

For example, the first organic pattern 209p1 may overlap the first red sub-pixel Pr1, the second red sub-pixel Pr2, the first green sub-pixel Pg1, and the second green sub-pixel Pg2. In this case, the first red sub-pixel Pr1 and the first green sub-pixel Pg1 may be apart from each other in the second direction (y direction), and the second red sub-pixel Pr2 and the second green sub-pixel Pg2 may be apart from each other in the second direction (y direction). The second organic pattern 209p2 may overlap the second sub-pixel group SG2. For example, the second organic pattern 209p2 may overlap the first blue sub-pixel Pb1 and the second blue sub-pixel Pb2.

The first red sub-pixel Pr1 and the first green sub-pixel Pg1 may overlap a boundary surface on the left side (−x direction) of the first organic pattern 209p1, and the first blue sub-pixel Pb1 may overlap a boundary surface on the left side (−x direction) of the second organic pattern 209p2. The second red sub-pixel Pr2 and the second green sub-pixel Pg2 may overlap a boundary surface on the right side (+x direction) of the first organic pattern 209p1, and the second blue sub-pixel Pb2 may overlap a boundary surface on the right side (+x direction) of the second organic pattern 209p2.

The first red sub-pixel Pr1, the first blue sub-pixel Pb1, and the first green sub-pixel Pg1 may be viewed by a user situated diagonally on the left side (−x direction) with respect to the third direction (z direction). The second red sub-pixel Pr2, the second blue sub-pixel Pb2, and the second green sub-pixel Pg2 may be viewed by a user situated diagonally on the right side (+x direction) with respect to the third direction (z direction). The third direction (z direction) is perpendicular to the upper surface of the substrate 100.

FIG. 7 is a schematic cross-sectional view of the display apparatus of FIG. 5, taken along line C-C′ of FIG. 5.

Referring to FIG. 7, the display apparatus 1 may include the substrate 100. As described with reference to FIG. 1, the display apparatus 1 may include the display area DA and the peripheral area PA. In the display area DA, the pixel circuit layer 200, the display element layer 300, the encapsulation layer 400, and the light-blocking layer 500 may be sequentially stacked on the substrate 100 in the third direction (z direction).

As described above, the substrate 100 may include a glass material or polymer resin. The pixel circuit layer 200 may be disposed on the substrate 100. The pixel circuit layer 200 may include a plurality of sub-pixel circuits PCr1, PCr2, PCb1, and PCb2, and insulating layers.

A buffer layer 201 may be disposed between the substrate 100 and the sub-pixel circuits PCr1, PCr2, PCb1, and PCb2. The buffer layer 201 may include an inorganic material such as silicon oxide (SiOₓ), silicon nitride (SiNₓ), and/or silicon oxynitride (SiOₓN_{y}). The buffer layer 201 may increase the flatness of the upper surface of the substrate 100 and prevent or reduce the penetration of impurities from the substrate 100 and the like into a semiconductor layer A.

Each of the sub-pixel circuits PCr1, PCr2, PCb1, and PCb2 may include a thin-film transistor TFT and a storage capacitor. The thin-film transistor TFT may include the semiconductor layer A, a gate electrode G, a source electrode S, and a drain electrode D, wherein the semiconductor layer A includes amorphous silicon, polycrystalline silicon, or an oxide semiconductor material. To secure insulation between the semiconductor layer A and the gate electrode G, a gate insulating layer 203 may be disposed between the semiconductor layer A and the gate electrode G. The gate insulating layer 203 includes inorganic materials such as silicon oxide (SiOₓ), silicon nitride (SiNₓ), and/or silicon oxynitride (SiOₓN_{y}).

An interlayer insulating layer 205 may be disposed on the gate electrode G, wherein the interlayer insulating layer 205 includes inorganic materials such as silicon oxide (SiOₓ), silicon nitride (SiNₓ), and/or silicon oxynitride (SiOₓN_{y}). The source electrode S and the drain electrode D may be disposed on the interlayer insulating layer 205. In some embodiments, one of the source electrode S and/or the drain electrode D might not exist.

Each of the gate electrode G, the source electrode S, and the drain electrode D may include various conductive materials. Each of the gate electrode G, the source electrode S, and the drain electrode D may have a single-layered structure or a multi-layered structure including at least one of molybdenum (Mo), aluminum (Al), copper (Cu), and/or titanium (Ti). In an embodiment, the gate electrode G may have a single Mo layer, and each of the source electrode S and the drain electrode D may have a three-layered structure including a titanium layer, an aluminum layer, and a titanium layer.

A planarization layer 207 may be disposed on the source electrode S and the drain electrode D, covering the sub-pixel circuits PCr1, PCr2, PCb1, and PCb2. The planarization layer 207 may include an organic material such as acrylic-based resin, benzocyclobutene (BCB), or hexamethyldisiloxane (HMDSO). The planarization layer 207 may have a single-layered or multi-layered structure.

An organic material layer 209 may be disposed on the pixel circuit layer 200. The organic material layer 209 may include a plurality of organic patterns including the first organic pattern 209p1 and the second organic pattern 209p2. The first organic pattern 209p1 may have a first slope surface ss1, a second slope surface ss2, and a first upper surface us1, wherein the first slope surface ss1 is inclined in a fourth direction DR4 oblique with respect to the upper surface of the substrate 100, the second slope surface ss2 is inclined in a fifth direction DR5 different from the fourth direction DR4, and the first upper surface us1 connects the first slope surface ss1 to the second slope surface ss2. The first slope surface ss1 and the second slope surface ss2 may be apart from each other in the first direction (x direction) with the first upper surface us1 therebetween. The second organic pattern 209p2 may have a third slope surface ss3, a fourth slope surface ss4, and a second upper surface us2, wherein the third slope surface ss3 is inclined in the fourth direction DR4, the fourth slope surface ss4 is inclined in the fifth direction DR5, and the second upper surface us2 connects the third slope surface ss3 to the fourth slope surface ss4. The third slope surface ss3 and the fourth slope surface ss4 may be apart from each other in the first direction (x direction) with the second upper surface us2 therebetween.

The first slope surface ss1 of the first organic pattern 209p1 may form a first angle θ1 counterclockwise with respect to an upper surface 207us of the planarization layer 207, and the second slope surface ss2 may form the first angle θ1 clockwise with respect to the upper surface 207us of the planarization layer 207. Likewise, the third slope surface ss3 of the second organic pattern 209p2 may form a second angle θ2 counterclockwise with respect to the upper surface 207us of the planarization layer 207, and the fourth slope surface ss4 may form the second angle θ2 clockwise with respect to the upper surface 207us of the planarization layer 207. The first angle θ1 and the second angle θ2 may be equal to or different from each other. For example, in an embodiment, the first angle θ1 and the second angle θ2 may be about 15° to about 60°. In some embodiments, the first angle θ1 and the second angle θ2 may be about 28°.

The first upper surface us1 of the first organic pattern 209p1 may have a first height h1 measured along the third direction (z direction) from the upper surface 207us of the planarization layer 207. The second upper surface us2 of the second organic pattern 209p2 may have a second height h2 measured along the third direction (z direction) from the upper surface 207us of the planarization layer 207. In an embodiment, the first height h1 and the second height h2 may be different from each other. For example, the first height h1 may be greater than the second height h2. The first height h1 and the second height h2 may be 10 μm or less.

In some embodiments, the organic material layer 209 may further include the third organic pattern 209p3 (See FIG. 5). The third organic pattern 209p3 may have a fifth slope surface, a sixth slope surface, and a third upper surface, wherein the fifth slope surface is inclined in the fourth direction DR4, the sixth slope surface is inclined in the fifth direction DR5, and the third upper surface connects the fifth slope surface to the sixth slope surface. The third upper surface of the third organic pattern 209p3 may have a third height measured along the third direction (z direction) from the upper surface 207us of the planarization layer 207. In an embodiment, the third height may be different from the first height h1 and the second height h2. For example, the third height may be greater than the first height h1 and/or the second height h2. In some embodiments, the third height may be equal to the first height h1. The third height may be 10 μm or less. The fifth slope surface of the third organic pattern 209p3 may form a third angle counterclockwise with respect to the upper surface 207us of the planarization layer 207, and the sixth slope surface may form the third angle clockwise with respect to the upper surface 207us of the planarization layer 207. The third angle may be equal to or different from the first angle θ1 and/or the second angle θ2.

The display element layer 300 may be disposed on the organic material layer 209. The display element layer 300 may include a plurality of light-emitting diodes EDr1, EDr2, EDb1, and EDb2, and a bank layer BNL.

For example, each of the light-emitting diodes EDr1, EDr2, EDb1, and EDb2 may include a pixel electrode 310, an opposite electrode 330, and an emission layer 320 disposed between the pixel electrode 310 and the opposite electrode 330.

The pixel electrodes 310 may be reflective electrodes. In an embodiment, the pixel electrode 310 may include a reflective layer and a transparent or semi-transparent electrode layer on the reflective layer. The reflective layer may include silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent or semi-transparent electrode layer may include at least one of indium tin oxide, indium zinc oxide, zinc oxide, indium oxide, indium gallium oxide, and/or aluminum zinc oxide. In an embodiment, the pixel electrode 310 may have a three-layered structure of an indium tin oxide (ITO) layer, an Ag layer, and an ITO layer.

The bank layer BNL may be disposed on the planarization layer 207 and the organic material layer 209, and cover the edges of the pixel electrodes 310. The bank layer BNL may define openings OP respectively exposing the upper surfaces of the pixel electrodes 310. The openings OP of the bank layer BNL may define an emission area EA of each sub-pixel. The bank layer BNL may cover the edges of the pixel electrode 310 and prevent arcs and the like from occurring at the edges of the pixel electrode 310 by increasing a distance between the edges of the pixel electrode 310 and the opposite electrode 330. The bank layer BNL may be formed by spin coating and the like using organic insulating materials such as polyimide, polyamide, acrylic-based resin, benzocyclobutene, hexamethyldisiloxane (HMDSO), and/or phenolic-based resin.

In an embodiment, the bank layer BNL may include a light-blocking material and be provided in black. The light-blocking material may include carbon black, carbon nanotubes, a resin or paste including black dye, metal particles, for example, nickel, aluminum, molybdenum, and an alloy thereof, metal oxide particles (e.g., chrome oxide) or metal nitride particles (e.g., chrome nitride). In the case where the bank layer BNL includes a light-blocking material, external light reflection by metal structures disposed below the bank layer BNL may be reduced.

In an embodiment, the organic material layer 209 may include the same material as that of the bank layer BNL. For example, the organic material layer 209 may include organic insulating materials such as polyimide, polyamide, acrylic resin, benzocyclobutene, hexamethyldisiloxane (HMDSO), and/or phenolic resin. In the case where the bank layer BNL includes a light-blocking material, the organic material layer 209 may include a light-blocking material.

The emission layer 320 may be disposed on the pixel electrode 310. The emission layer 320 may include an organic material including a fluorescent or phosphorous material that emit blue, green, or red light. The organic material may include a low molecular weight organic material or a polymer organic material. The emission layer 320 may be disposed inside the openings OP of the bank layer BNL to correspond to the pixel electrode 310.

A first common layer and/or a second common layer may be respectively disposed under and on the emission layer 320. The first common layer is an element disposed under the emission layer 320 and may include, for example, a hole transport layer (HTL), or include an HTL and/or a hole injection layer (HIL). The second common layer is an element disposed on the emission layer 320 and may include an electron transport layer (ETL) and/or an electron injection layer (EIL). In some embodiments, the second common layer may not be provided.

Like the opposite electrode 330 described below, the first common layer and the second common layer may be common layers that are integrally formed, covering the display area DA entirely.

The opposite electrode 330 may be a cathode which is an electron injection electrode. A metal, alloy, electrically conductive compound, or an arbitrary combination thereof having a low work function may be used as the material forming the opposite electrode 330. The opposite electrode 330 may be a transmissive electrode, a semi-transmissive electrode, or a reflective electrode. The opposite electrode 330 may be integrally formed over the plurality of light-emitting diodes EDr1, EDr2, EDb1, and EDb2, covering the display area DA entirely.

The opposite electrode 330 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, indium zinc oxide (IZO), or any combination thereof. The opposite electrode 330 may have a single-layered structure or a multi-layered structure.

In an embodiment, a capping layer may be further disposed on the opposite electrode 330. The capping layer may increase an external light-emission efficiency of an organic light-emitting element based on a constructive interference principle. The capping layer may include a material having a refractive index of about 1.6 (with respect to a light a wavelength of which is at about 589 nm). The capping layer may be an organic capping layer including an organic material, an inorganic capping layer including an inorganic material, or a composite capping layer including an organic material and an inorganic material.

The first organic pattern 209p1 may overlap the first sub-pixel group SG1. The first sub-pixel group SG1 may include the first red sub-pixel Pr1 and the second red sub-pixel Pr2. The first red sub-pixel Pr1 may include the first light-emitting diode EDr1 and the first sub-pixel circuit PCr1 electrically connected to the first light-emitting diode EDr1. The second red sub-pixel Pr2 may include the second light-emitting diode EDr2 and the second sub-pixel circuit PCr2 electrically connected to the second light-emitting diode EDr2. The first light-emitting diode EDr1 may be configured to emit light according to an electrical signal applied to the first sub-pixel circuit PCr1, and the second light-emitting diode EDr2 may be configured to emit light according to an electrical signal applied to the second sub-pixel circuit PCr2. For example, the first light-emitting diode EDr1 and the second light-emitting diode EDr2 may be configured to emit light according to different electrical signals.

The first light-emitting diode EDr1 may be disposed on the first slope surface ss1 of the first organic pattern 209p1. For example, the pixel electrode 310 of the first light-emitting diode EDr1 may extend from the upper surface 207us of the planarization layer 207 to the first upper surface us1 of the first organic pattern 209p1 through the first slope surface ss1 of the first organic pattern 209p1. The second light-emitting diode EDr2 may be disposed on the second slope surface ss2 of the first organic pattern 209p1. For example, the pixel electrode 310 of the second light-emitting diode EDr2 may extend from the upper surface 207us of the planarization layer 207 to the first upper surface us1 of the first organic pattern 209p1 through the second slope surface ss2 of the first organic pattern 209p1.

The second organic pattern 209p2 may overlap the second sub-pixel group SG2. The second sub-pixel group SG2 may include the first blue sub-pixel Pb1 and the second blue sub-pixel Pb2. The first blue sub-pixel Pb1 may include the third light-emitting diode EDb1 and the third sub-pixel circuit PCb1 electrically connected to the third light-emitting diode EDb1. The second blue sub-pixel Pb2 may include the fourth light-emitting diode EDb2 and the fourth sub-pixel circuit PCb2 electrically connected to the fourth light-emitting diode EDb2. The third light-emitting diode EDb1 may be configured to emit light according to an electrical signal applied to the third sub-pixel circuit PCb1, and the fourth light-emitting diode EDb2 may be configured to emit light according to an electrical signal applied to the fourth sub-pixel circuit PCb2. The third light-emitting diode EDb1 and the fourth light-emitting diode EDb2 may be configured to emit light according to different electrical signals.

The third light-emitting diode EDb1 may be disposed on the third slope surface ss3 of the second organic pattern 209p2. For example, the pixel electrode 310 of the third light-emitting diode EDb1 may extend from the upper surface 207us of the planarization layer 207 to the second upper surface us2 of the second organic pattern 209p2 through the third slope surface ss3 of the second organic pattern 209p2. The fourth light-emitting diode EDb2 may be disposed on the fourth slope surface ss4 of the second organic pattern 209p2. The pixel electrode 310 of the fourth light-emitting diode EDb2 may extend from the upper surface 207us of the planarization layer 207 to the second upper surface us2 of the second organic pattern 209p2 through the fourth slope surface ss4 of the second organic pattern 209p2.

The bank layer BNL may define the openings OP respectively overlapping the light-emitting didoes EDr1, EDr2, EDb1, and EDb2. The openings OP corresponding to the light-emitting didoes EDr1, EDr2, EDb1, and EDb2 may respectively overlap the first slope surface ss1, the second slope surface ss2, the third slope surface ss3, and the fourth slope surface ss4.

The first light-emitting diode EDr1 and the second light-emitting diode EDr2 may be configured to emit light of the same color. For example, the first light-emitting diode EDr1 and the second light-emitting diode EDr2 may be configured to emit red light. The third light-emitting diode EDb1 and the fourth light-emitting diode EDb2 may be configured to emit light of the same color. For example, the third light-emitting diode EDb1 and the fourth light-emitting diode EDb2 may be configured to emit blue light.

As described with reference to FIG. 5, the third sub-pixel group SG3 overlapping the third organic pattern 209p3 may be arranged. The third sub-pixel group SG3 may include the first green sub-pixel Pg1 and the second green sub-pixel Pg2. The first green sub-pixel Pg1 may include a fifth light-emitting diode and a fifth sub-pixel circuit electrically connected to the fifth light-emitting diode. The second green sub-pixel Pg2 may include a sixth light-emitting diode and a sixth sub-pixel circuit electrically connected to the sixth light-emitting diode. The fifth light-emitting diode may be configured to emit light according to an electrically signal applied to the fifth sub-pixel circuit, and the sixth light-emitting diode may be configured to emit light according to an electrically signal applied to the sixth sub-pixel circuit. The fifth light-emitting diode and the sixth light-emitting diode may be configured to emit light according to different electrical signals.

The fifth light-emitting diode may be disposed on the fifth slope surface of the third organic pattern 209p3. For example, a pixel electrode 310 of the fifth light-emitting diode may extend from the upper surface 207us of the planarization layer 207 to a third upper surface of the third organic pattern 209p3 through the fifth slope surface of the third organic pattern 209p3. A pixel electrode 310 of the sixth light-emitting diode may extend from the upper surface 207us of the planarization layer 207 to a third upper surface of the third organic pattern 209p3 through the sixth slope surface of the third organic pattern 209p3.

In some embodiments, as described with reference to FIG. 6, the third sub-pixel group SG3 overlapping the first organic pattern 209p1 extending in the second direction (y direction) may be disposed. In this case, the fifth light-emitting diode may be disposed on the first slope surface ss1 of the first organic pattern 209p1. The pixel electrode 310 of the fifth light-emitting diode may extend from the upper surface 207us of the planarization layer 207 to the first upper surface us1 of the first organic pattern 209p1 through the first slope surface ss1 of the first organic pattern 209p1. The sixth light-emitting diode may be disposed on the second slope surface ss2 of the first organic pattern 209p1. For example, the pixel electrode 310 of the sixth light-emitting diode may extend from the upper surface 207us of the planarization layer 207 to the first upper surface us1 of the first organic pattern 209p1 through the second slope surface ss2 of the first organic pattern 209p1.

The openings OP of the bank layer BNL may be different in their sizes depending on emission efficiencies of the light-emitting diodes EDr1, EDr2, EDb1, and EDb2. Accordingly, the widths (or the areas) of the emission areas EA defined by the openings OP may be different from each other. For example, the width (or the area) of the emission area EA of each of the third light-emitting diode EDb1 and the fourth light-emitting diode EDb2 configured to emit blue light may be less than the width (or the area) of the emission area EA of each of the first light-emitting diode EDr1 and the second light-emitting diode EDr2 configured to emit red light.

The encapsulation layer 400 encapsulating the light-emitting diodes EDr1, EDr2, EDb1, and EDb2 may be disposed on the display element layer 300. The encapsulation layer 400 may include at least one inorganic encapsulation layer and at least one organic encapsulation layer. For example, the inorganic encapsulation layer may include at least one inorganic material among aluminum oxide (Al₂O₃), titanium oxide (TiO₂), tantalum oxide (Ta₂O₅), zinc oxide (ZnOₓ, may be ZnO or ZnO₂), silicon oxide (SiOₓ), silicon nitride (SiNₓ), and/or silicon oxynitride (SiOₓN_{y}). For example, the organic encapsulation layer may include a polymer-based material such as an acryl-based resin, an epoxy-based resin, polyimide, and/or polyethylene. In an embodiment, the at least one organic encapsulation layer may include acrylate. It is shown in FIG. 7 that the encapsulation layer 400 may include a first inorganic encapsulation layer 410, a second inorganic encapsulation layer 430, and an organic encapsulation layer 420 disposed between the first inorganic encapsulation layer 410 and the second inorganic encapsulation layer 430. The organic encapsulation layer 420 may cover the unevenness of the light-emitting diodes EDr1, EDr2, EDb1, and EDb2 and provide a flat upper surface.

The light-blocking layer 500 may be disposed on the encapsulation layer 400. The light-blocking layer 500 may include a light-blocking pattern 510 and an overcoat layer 520.

The light-blocking pattern 510 may be disposed on the second inorganic encapsulation layer 430. The light-blocking pattern 510 may include a light-absorption material and/or a low-reflective material. The light-blocking pattern 510 may define light-transmissive openings 510OP overlapping the openings OP of the bank layer BNL. A body portion of the light-blocking pattern 510 may overlap a body portion of the bank layer BNL. The body portion of the light-blocking pattern 510 is differentiated from the light-transmissive openings 510OP and denotes a portion having a preset volume. Likewise, the body portion of the bank layer BNL is differentiated from the openings OP and denotes a portion having a preset volume.

The width (or the area) of each of the light-transmissive openings 510OP may be changed by the width (or the area) of the opening OP corresponding thereto. For example, the width (or the area) of the light-transmissive opening 510OP overlapping the first red sub-pixel Pr1 may be greater than the width (or the area) of the light-transmissive opening 510OP overlapping the first blue sub-pixel Pb1.

The body portion of the light-blocking pattern 510 may define a light-blocking area SHA blocking light emitted by the light-emitting diodes EDr1, EDr2, EDb1, and EDb2. The light-transmissive openings 510OP of the light-blocking pattern 510 may define a transmissive area TA through which light emitted by the light-emitting diodes EDr1, EDr2, EDb1, and EDb2 may pass. Because the light-transmissive openings 510OP of the light-blocking pattern 510 overlap the openings OP of the bank layer BNL, the transmissive areas TA may overlap the emission areas EA.

In this case, the pixel electrode 310 is oblique with respect to the upper surface of the substrate 100 and the center of the transmissive area TA may not coincide with the center of the emission area EA. For example, the center of the transmissive area TA that overlaps the first light-emitting diode EDr1 may be located on the left (−x direction) of the center of the emission area EA of the first light-emitting diode EDr1. The center of the transmissive area TA that overlaps the second light-emitting diode EDr2 may be located on the right (+x direction) of the center of the emission area EA of the second light-emitting diode EDr2. Likewise, the center of the transmissive area TA that overlaps the third light-emitting diode EDb1 may be located on the left (−x direction) of the center of the emission area EA of the third light-emitting diode EDb1, and the center of the transmissive area TA that overlaps the fourth light-emitting diode EDb2 may be located on the right (+x direction) of the center of the emission area EA of the fourth light-emitting diode EDb2.

In the case where light emitted by the light-emitting diodes EDr1, EDr2, EDb1, and EDb2 has a preset angle, the emitted light may be absorbed by the light-blocking pattern 510. Accordingly, light emitted by some of the sub-pixels P may be blocked depending on a user's position.

The overcoat layer 520 may be disposed on the light-blocking pattern 510 to cover the light-blocking pattern 510. The overcoat layer 520 may cover the light-transmissive openings 510OP of the light-blocking pattern 510 and provide a flat upper surface. The overcoat layer 520 may include a light-transmissive organic material. For example, the overcoat layer 520 may include acrylic-based resin (e.g., polymethyl methacrylate, polyacrylic acid, etc.), ethylhexyl acrylate, pentafluoropropyl acrylate, polyethylene glycol dimethacrylate, poly(ethylene glycol) dimethacrylate or ethylene glycol dimethacrylate.

In an embodiment, the light-blocking pattern 510 may include a plurality of layers. For example, the light-blocking pattern 510 may include a first light-blocking pattern and a second light-blocking pattern. One or more light-transmissive material layer may be disposed between the first light-blocking pattern and the second light-blocking pattern.

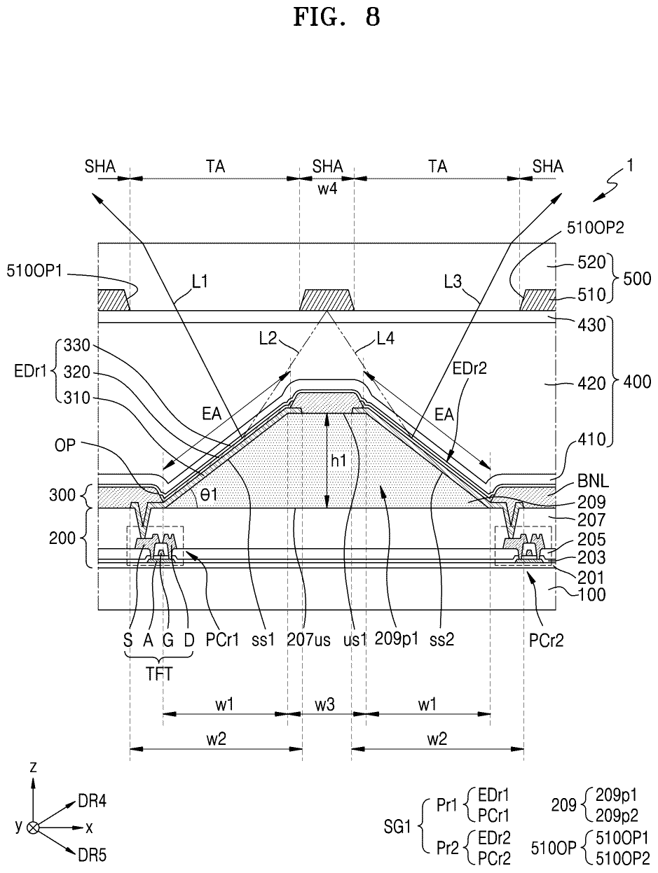

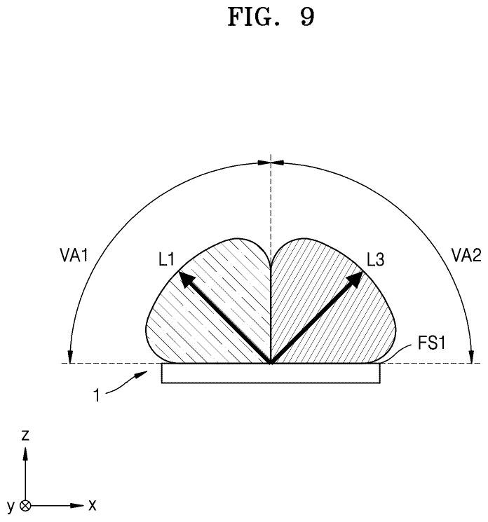

FIG. 8 is a view for explaining a path of light emitted by the display apparatus 1 according to an embodiment of the inventive concept, and FIG. 9 is a view for explaining a dual-view display apparatus according to an embodiment of the inventive concept.

Referring to FIG. 8, the display apparatus 1 may include the substrate 100. The pixel circuit layer 200 may be disposed on the substrate 100, wherein the pixel circuit layer 200 includes the first sub-pixel circuit PCr1, the second sub-pixel circuit PCr2, the buffer layer 201, the gate insulating layer 203, the interlayer insulating layer 205, and the planarization layer 207.

The first organic pattern 209p1 may be disposed on the pixel circuit layer 200. The first organic pattern 209p1 may have a first slope surface ss1, a second slope surface ss2, and a first upper surface us1. The first slope surface ss1 is inclined in a fourth direction DR4 oblique with respect to the upper surface of the substrate 100, the second slope surface ss2 is inclined in a fifth direction DR5 different from the fourth direction DR4. The first upper surface us1 connects the first slope surface ss1 to the second slope surface ss2. The first slope surface ss1 of the first organic pattern 209p1 may form the first angle θ1 counterclockwise with respect to the upper surface 207us of the planarization layer 207. The second slope surface ss2 of the first organic pattern 209p1 may form the first angle θ1 clockwise with respect to the upper surface 207us of the planarization layer 207. The first upper surface us1 of the first organic pattern 209p1 may have the first height h1 measured in the third direction (z direction) from the upper surface 207us of the planarization layer 207. The first height h1 may be 10 μm or less.

The display element layer 300 may be disposed on the planarization layer 207 and the first organic pattern 209p1. The display element layer 300 may include the first light-emitting diode EDr1, the second light-emitting diode EDr2, and the bank layer BNL.

Each of the first light-emitting diode EDr1 and the second light-emitting diode EDr2 may include the pixel electrode 310, the opposite electrode 330, and the emission layer 320 disposed between the pixel electrode 310 and the opposite electrode 330.

The bank layer BNL may be disposed on the planarization layer 207 and the first organic pattern 209p1, covering the edges of the pixel electrodes 310. The bank layer BNL may define the openings OP respectively exposing the upper surfaces of the pixel electrodes 310. The openings OP of the bank layer BNL may define an emission area EA of each sub-pixel P (see FIG. 3). In an embodiment, the first organic pattern 209p1 may include the same material as that of the bank layer BNL.

The first organic pattern 209p1 may overlap the first sub-pixel group SG1. The first sub-pixel group SG1 may include the first red sub-pixel Pr1 and the second red sub-pixel Pr2. The first red sub-pixel Pr1 may include the first light-emitting diode EDr1 and the first sub-pixel circuit PCr1 electrically connected to the first light-emitting diode EDr1. The second red sub-pixel Pr2 may include the second light-emitting diode EDr2 and the second sub-pixel circuit PCr2 electrically connected to the second light-emitting diode EDr2. The first light-emitting diode EDr1 and the second light-emitting diode EDr2 may be configured to emit light of the same color.

The first light-emitting diode EDr1 may be disposed on the first slope surface ss1 of the first organic pattern 209p1. For example, the pixel electrode 310 of the first light-emitting diode EDr1 may extend from the upper surface 207us of the planarization layer 207 to the first upper surface us1 of the first organic pattern 209p1 through the first slope surface ss1 of the first organic pattern 209p1. The second light-emitting diode EDr2 may be disposed on the second slope surface ss2 of the first organic pattern 209p1. For example, the pixel electrode 310 of the second light-emitting diode EDr2 may extend from the upper surface 207us of the planarization layer 207 to the first upper surface us1 of the first organic pattern 209p1 through the second slope surface ss2 of the first organic pattern 209p1.

When viewed in a direction perpendicular to the upper surface of the substrate 100 (e.g., in a plan view), the first slope surface ss1 of the first organic pattern 209p1 may have a first width w1 measured along the first direction (x direction). In a plan view, the pixel electrode 310 of the first light-emitting diode EDr1 may have a second width w2 measured along the first direction (x direction). The first width w1 may be less than the second width w2.

In a plan view, the second slope surface ss2 of the second organic pattern 209p2 may have the first width w1 measured along the first direction (x direction) like the first slope surface ss1. Like the pixel electrode 310 of the first light-emitting diode EDr1, the pixel electrode 310 of the second light-emitting diode EDr2 may have the second width w2 measured along the first direction (x direction).

In this case, a contact portion may be disposed on the upper surface 207us of the planarization layer 207. The contact portion connects the pixel electrode 310 of the first light-emitting diode EDr1 to the first sub-pixel circuit PCr1. Likewise, a contact portion may be disposed on the upper surface 207us of the planarization layer 207, wherein the contact portion connects the pixel electrode 310 of the second light-emitting diode EDr2 to the second sub-pixel circuit PCr2.

The openings OP of the bank layer BNL may overlap the first slope surface ss1 or the second slope surface ss2. In an embodiment, when viewed in a plan, the openings OP of the bank layer BNL may be disposed inside the first slope surface ss1 and the second slope surface ss2.

The first slope surface ss1 of the first organic pattern 209p1 forms the first angle θ1 counterclockwise with respect to the upper surface 207us of the planarization layer 207, and first light L1 emitted perpendicular to the pixel electrode 310 of the first light emitting diode EDr1 may proceed counterclockwise, oblique by the first angle θ1 with respect to the third direction (z direction) which is perpendicular to the upper surface of the substrate 100. The second slope surface ss2 of the first organic pattern 209p1 forms the first angle θ1 clockwise with respect to the upper surface 207us of the planarization layer 207, and third light L3 emitted perpendicular to the pixel electrode 310 of the second light emitting diode EDr2 may proceed clockwise, oblique by the first angle θ1 with respect to the third direction (z direction) which is perpendicular to the upper surface of the substrate 100.

Accordingly, a primary light angle of the first light-emitting diode EDr1 and the second light-emitting diode EDr2 may be modified by adjusting the first angle θ1 depending on a user's position which may be the positions of a driver's seat and the passenger seat of a vehicle. In an embodiment, in the case where the driver's seat and the passenger seat of a vehicle are located at +45° with respect to the third direction (z direction) perpendicular to the front surface FS1 (see FIG. 2) of the display apparatus 1, the first angle θ1 may be about 28°.

The body portion of the bank layer BNL may be disposed on the first upper surface us1 of the first organic pattern 209p1. The body portion of the bank layer BNL arranged between adjacent emission areas EA may have a third width w3. For example, the emission area EA of the first light-emitting diode EDr1 and the emission area EA of the second light-emitting diode EDr2 may be spaced apart from each other by the third width w3.

The encapsulation layer 400 may be disposed on the display element layer 300, wherein the encapsulation layer 400 encapsulates the first light-emitting diode EDr1 and the second light-emitting diode EDr2. The encapsulation layer 400 may include a first inorganic encapsulation layer 410, a second inorganic encapsulation layer 430, and an organic encapsulation layer 420 disposed between the first inorganic encapsulation layer 410 and the second inorganic encapsulation layer 430.

The light-blocking layer 500 may be disposed on the encapsulation layer 400. The light-blocking layer 500 may include the light-blocking pattern 510 and the overcoat layer 520. The light-blocking pattern 510 may define the light-transmissive openings 510OP overlapping the openings OP of the bank layer BNL. The body portion of the light-blocking pattern 510 may overlap the body portion of the bank layer BNL. The body portion of the light-blocking pattern 510 may define the light-blocking area SHA. The light-transmissive openings 510OP of the light-blocking pattern 510 may define the transmissive area TA. The body portion of the light-blocking pattern 510 arranged between adjacent transmissive areas TA may have a fourth width w4.

The light-blocking pattern 510 may be configured to absorb a portion of light emitted by the light-emitting diodes EDr1 and EDr2. The second light L2 emitted oblique to the right (+x direction) from the pixel electrode 310 of the first light-emitting diode EDr1 may be absorbed by the body portion of the light-blocking pattern 510. Likewise, the fourth light L4 emitted oblique to the left (−x direction) from the pixel electrode 310 of the second light-emitting diode EDr2 may be absorbed by the body portion of the light-blocking pattern 510. Only light emitted from the first light-emitting diode EDr1 may pass through the transmissive area TA defined by the first light-blocking opening 510OP1, and only light from the second light-emitting diode EDr2 may pass through the transmissive area TA defined by the second light-blocking opening 510OP2. A viewing angle of light emitted from the first light-emitting diode EDr1 and the second light-emitting diode EDr2 may be determined by adjusting the third width w3 of the bank layer BNL and the fourth width w4 of the light-blocking pattern 510.

The overcoat layer 520 may be disposed on the light-blocking pattern 510 to cover the light-blocking pattern 510. The overcoat layer 520 may bury the light-transmissive openings 510OP of the light-blocking pattern 510 to provide a flat upper surface.

Referring to FIG. 9 and in conjunction with FIGS. 3, and 7, the display apparatus 1 may be configured to implement a dual view providing different images depending on a user's position. For example, in the case where a user's position belongs to a first view area VA1, which is located in a left (−x direction) diagonal direction of the front surface FS1 of the display apparatus 1, only light emitted by a first red sub-pixel Pr1 among sub-pixels P in the first sub-pixel group SG1 may reach the user. In contrast, in the case where a user's position belongs to a second view area VA2, which is located in a right (+x direction) diagonal direction of the front surface FS1 of the display apparatus 1, only light emitted by a second red sub-pixel Pr2 among sub-pixels P in the first sub-pixel group SG1 may reach the user.

In this case, among light emitted by the first red sub-pixel Pr1, the first light L1 emitted perpendicular to the pixel electrode 310 of the first light-emitting diode EDr1 may have strongest intensity. As described above, the direction of the first light L1 may be adjusted by the first angle θ1 which is an angle formed by the first slope surface ss1 of the first organic pattern 209p1 and the upper surface 207us of the planarization layer 207. Among light emitted by the first red sub-pixel Pr1, light emitted in a direction of the second view area VA2 may be absorbed by the body portion of the light-blocking pattern 510.

Among light emitted by the second red sub-pixel Pr2, the third light L3 emitted perpendicular to the pixel electrode 310 of the second light-emitting diode EDr2 may have strongest intensity. The direction of the third light L3 may be adjusted by the first angle θ1 which is an angle formed by the second slope surface ss2 of the first organic pattern 209p1 and the upper surface 207us of the planarization layer 207. Among light emitted by the second red sub-pixel Pr2, light emitted in a direction of the first view area VA1 may be absorbed by the body portion of the light-blocking pattern 510.

Accordingly, the display apparatus 1 may be configured to provide different two images to the first view area VA1 and the second view area VA2.

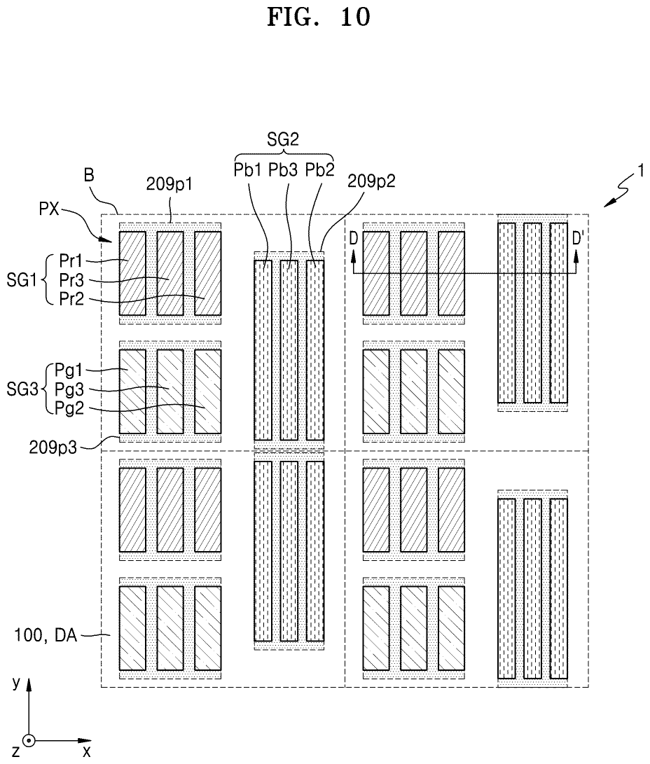

FIG. 10 is a schematic enlarged plan view of a portion of the display apparatus 1 according to an embodiment of the inventive concept. FIG. 10 schematically shows a region B of the display apparatus 1 shown in FIG. 3.

Referring to FIG. 10, the display apparatus 1 may include the substrate 100 (See FIG. 3). A plurality of pixels PX may be arranged in the display area DA (See FIG. 3) of the substrate 100. Each pixel PX may include sub-pixels P (e.g., see FIG. 3) configured to emit light of one of red, green, blue, and white. For example, it is shown in FIG. 10 that a pixel PX includes three red sub-pixels Pr1, Pr2, and Pr3, three green sub-pixels Pg1, Pg2, and Pg3, and three blue sub-pixels Pb1, Pb2, and Pb3. In an embodiment, a pixel PX may further include three white sub-pixels.

A plurality of organic patterns may be disposed on the substrate 100. Each organic pattern may have two slope surfaces inclined in different directions and one upper surface disposed between the slope surfaces.

An organic pattern may overlap a sub-pixel group SG1, SG2 and SG3 including sub-pixels P configured to emit light of the same color. For example, the first organic pattern 209p1 may overlap the first sub-pixel group SG1 including the first red sub-pixel Pr1, the second red sub-pixel Pr2, and the third red sub-pixel Pr3, the second organic pattern 209p2 may overlap the second sub-pixel group SG2 including the first blue sub-pixel Pb1, the second blue sub-pixel Pb2, and the third blue sub-pixel Pb3, and the third organic pattern 209p3 may overlap the third sub-pixel group SG3 including the first green sub-pixel Pg1, the second green sub-pixel Pg2, and the third green sub-pixel Pg3.

Sub-pixels P in each sub-pixel group SG1, SG2 and SG3 may be apart from each other in the first direction (x direction). For example, the first red sub-pixel Pr1, the second red sub-pixel Pr2, and the third red sub-pixel Pr3 in the first sub-pixel group SG1 may be sequentially apart from each other in the first direction (x direction), the first blue sub-pixel Pb1, the second blue sub-pixel Pb2, and the third blue sub-pixel Pb3 in the second sub-pixel group SG2 may be sequentially apart from each other in the first direction (x direction), and the first green sub-pixel Pg1, the second green sub-pixel Pg2, and the third green sub-pixel Pg3 in the third sub-pixel group SG3 may be sequentially apart from each other in the first direction (x direction).

The first organic pattern 209p1 and the second organic pattern 209p2 may be apart from each other in the first direction (the x direction). Accordingly, the first sub-pixel group SG1 and the second sub-pixel group SG2 may be apart from each other in the first direction (the x direction).

The first organic pattern 209p1 and the third organic pattern 209p3 may be apart from each other in the second direction (the y direction). Accordingly, the first sub-pixel group SG1 and the third sub-pixel group SG3 may be apart from each other in the second direction (y direction). For example, the first red sub-pixel Pr1 and the first green sub-pixel Pg1 may be apart from each other in the second direction (y direction), the second red sub-pixel Pr2 and the second green sub-pixel Pg2 may be apart from each other in the second direction (y direction), and the third red sub-pixel Pr3 and the third green sub-pixel Pg3 may be apart from each other in the second direction (y direction).

One of sub-pixels P included in each sub-pixel group SG1, SG2 and SG3 may overlap a slope surface on one side of the organic patterns, another sub-pixel P of sub-pixels P included in each sub-pixel group SG1, SG2 and SG3 may overlap a slope surface on another side of the organic patterns, still another sub-pixel P may overlap the upper surfaces of the organic patterns.

For example, the first red sub-pixel Pr1, the first blue sub-pixel Pb1, and the first green sub-pixel Pg1 may respectively overlap a boundary surface on the left side (−x direction) of the first organic pattern 209p1, a boundary surface on the left side (−x direction) of the second organic pattern 209p2, and a boundary surface on the left side (−x direction) of the third organic pattern 209p3. The second red sub-pixel Pr2, the second blue sub-pixel Pb2, and the second green sub-pixel Pg2 may respectively overlap a boundary surface on the right side (+x direction) of the first organic pattern 209p1, a boundary surface on the right side (+x direction) of the second organic pattern 209p2, and a boundary surface on the right side (+x direction) of the third organic pattern 209p3. The third red sub-pixel Pr3, the third blue sub-pixel Pb3, and the third green sub-pixel Pg3 may respectively overlap the upper surfaces of the first organic pattern 209p1, the second organic pattern 209p2, and the third organic pattern 209p3.

Sub-pixels P arranged on the boundary surfaces on the left side (−x direction) of the organic patterns. For example, the first red sub-pixel Pr1, the first blue sub-pixel Pb1, and the first green sub-pixel Pg1 may be viewed by a user situated diagonally on the left side (−x direction) with respect to the third direction (z direction) perpendicular to the upper surface of the substrate 100. Sub-pixels P arranged on the boundary surfaces on the right side (+x direction) of the organic patterns. For example, the second red sub-pixel Pr2, the second blue sub-pixel Pb2, and the second green sub-pixel Pg2 may be viewed by a user situated diagonally on the right side (the +x direction) with respect to the third direction (z direction) perpendicular to the upper surface of the substrate 100. The sub-pixels P disposed on the upper surfaces of the organic patterns. For example, the third red sub-pixel Pr3, the third blue sub-pixel Pb3, and the third green sub-pixel Pg3 may be viewed by a user positioned in the third direction (z direction) perpendicular to the upper surface of the substrate 100. Accordingly, the display apparatus 1 may be configured to display different images depending on a user's position.

In another embodiment, one organic pattern may extend in the second direction (the y direction) and overlap the pixels PX arranged in the same column. For example, each of the first organic pattern 209p1 and the second organic pattern 209p2 may extend in the second direction (y direction) to overlap one or more pixels PX. The first organic pattern 209p1 and the second organic pattern 209p2 may be apart from each other in the first direction (x direction). In this case, the third sub-pixel group SG3 may overlap the first organic pattern 209p1, and the first sub-pixel groups SG1 and the third sub-pixel groups SG3 may be alternately arranged in the second direction (y direction).

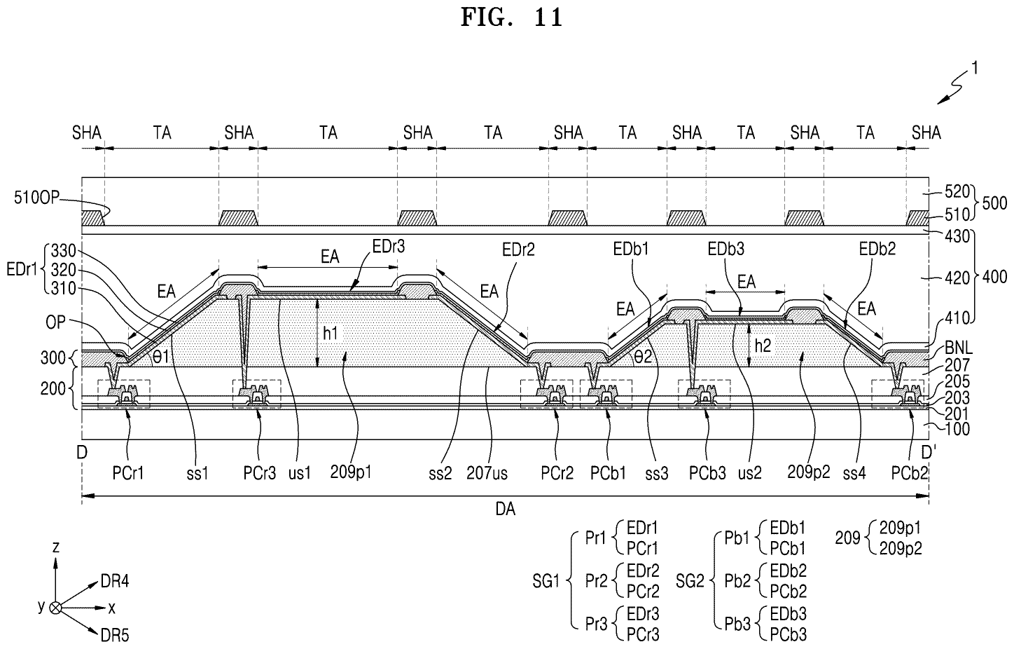

FIG. 11 is a schematic cross-sectional view of a display apparatus of FIG. 10, taken along line D-D′ of FIG. 10. FIG. 11 is similar to FIG. 7 but is different in that each of the first sub-pixel group SG1 and the second sub-pixel group SG2 includes three sub-pixels P. To the extent that details are not described, it may be assumed that the elements are at least similar to corresponding elements described in previous figures.

In the display area DA, the pixel circuit layer 200, the display element layer 300, the encapsulation layer 400, and the light-blocking layer 500 may be sequentially stacked on the substrate 100 in the third direction (z direction).

The pixel circuit layer 200 may be disposed on the substrate 100. The pixel circuit layer 200 may include a plurality of sub-pixel circuits PCr1, PCr2, PCr3, PCb1, PCb2, and PCb3, the buffer layer 201, the gate insulating layer 203, the interlayer insulating layer 205, and the planarization layer 207.

The organic material layer 209 may be disposed on the pixel circuit layer 200. The organic material layer 209 may include a plurality of organic patterns including the first organic pattern 209p1 and the second organic pattern 209p2. The first organic pattern 209p1 may have a first slope surface ss1, a second slope surface ss2, and a first upper surface us1, wherein the first slope surface ss1 is inclined in a fourth direction DR4 oblique with respect to the upper surface of the substrate 100, the second slope surface ss2 is inclined in a fifth direction DR5 different from the fourth direction DR4, and the first upper surface us1 connects the first slope surface ss1 to the second slope surface ss2. The second organic pattern 209p2 may have a third slope surface ss3, a fourth slope surface ss4, and a second upper surface us2, wherein the third slope surface ss3 is inclined in the fourth direction DR4, the fourth slope surface ss4 is inclined in the fifth direction DR5, and the second upper surface us2 connects the third slope surface ss3 to the fourth slope surface ss4.

The first slope surface ss1 of the first organic pattern 209p1 may form the first angle θ1 counterclockwise with respect to the upper surface 207us of the planarization layer 207. The second slope surface ss2 of the first organic pattern 209p1 may form the first angle θ1 clockwise with respect to the upper surface 207us of the planarization layer 207. The third slope surface ss3 of the second organic pattern 209p2 may form the second angle θ2 counterclockwise with respect to the upper surface 207us of the planarization layer 207. The fourth slope surface ss4 of the second organic pattern 209p2 may form the second angle θ2 clockwise with respect to the upper surface 207us of the planarization layer 207. The first angle θ1 and the second angle θ2 may be equal to or different from each other. In an embodiment, the first angle θ1 and the second angle θ2 may be about 15° to about 60°. In some embodiments, the first angle θ1 and the second angle θ2 may be about 28°.

The first upper surface us1 of the first organic pattern 209p1 may have the first height h1 measured along the third direction (z direction) from the upper surface 207us of the planarization layer 207. The second upper surface us2 of the second organic pattern 209p2 may have a second height h2 measured along the third direction (z direction) from the upper surface 207us of the planarization layer 207. In an embodiment, the first height h1 and the second height h2 may be different from each other. For example, the first height h1 may be greater than the second height h2. The first height h1 and the second height h2 may be 10 μm or less.

As described with reference to FIG. 10, in an embodiment, the organic material layer 209 may further include the third organic pattern 209p3. The third organic pattern 209p3 may have a fifth slope surface, the sixth slope surface, and the third upper surface, wherein the fifth slope surface is inclined in the fourth direction DR4, the sixth slope surface is inclined in the fifth direction DR5, and the third upper surface connects the fifth slope surface to the sixth slope surface. The fifth slope surface of the third organic pattern 209p3 may form a third angle counterclockwise with respect to the upper surface 207us of the planarization layer 207, and the sixth slope surface may form the third angle clockwise with respect to the upper surface 207us of the planarization layer 207. The third angle may be equal to or different from the first angle θ1 and/or the second angle θ2. The third upper surface of the third organic pattern 209p3 may have a third height measured along the third direction (z direction) from the upper surface 207us of the planarization layer 207. In an embodiment, the third height may be different from the first height h1 and the second height h2. For example, the third height may be greater than the first height h1 and the second height h2. In an embodiment, the third height may be equal to the first height h1. The third height may be 10 μm or less.

The display element layer 300 may be disposed on the organic material layer 209. The display element layer 300 may include a plurality of light-emitting diodes EDr1, EDr2, EDr3, EDb1, EDb2, and EDb3, and a bank layer BNL. Each of the light-emitting diodes EDr1, EDr2, EDr3, EDb1, EDb2, and EDb3 may include the pixel electrode 310, the opposite electrode 330, and the emission layer 320 disposed between the pixel electrode 310 and the opposite electrode 330.

The bank layer BNL may be disposed on the planarization layer 207 and the organic material layer 209 to cover the edges of the pixel electrodes 310. The bank layer BNL may define openings OP respectively exposing the upper surfaces of the pixel electrodes 310. The openings OP of the bank layer BNL may define an emission area EA of each sub-pixel P. In an embodiment, the organic material layer 209 may include the same material as that of the bank layer BNL.

The emission layer 320 may be disposed on the pixel electrode 310. The emission layer 320 may be disposed inside the openings OP of the bank layer BNL to correspond to the pixel electrode 310. The first common layer and/or the second common layer may be respectively disposed under and on the emission layer 320.

The opposite electrode 330 may be disposed on the emission layer 320. The opposite electrode 330 may be integrally formed over the plurality of light-emitting diodes EDr1, EDr2, EDr3, EDb1, EDb2, and EDb3 and cover the display area DA entirely.

The first organic pattern 209p1 may overlap the first sub-pixel group SG1. The first sub-pixel group SG1 may include the first red sub-pixel Pr1, the second red sub-pixel Pr2, and the third red sub-pixel Pr3. The first red sub-pixel Pr1 may include the first light-emitting diode EDr1 and the first sub-pixel circuit PCr1 electrically connected to the first light-emitting diode EDr1. The second red sub-pixel Pr2 may include the second light-emitting diode EDr2 and the second sub-pixel circuit PCr2 electrically connected to the second light-emitting diode EDr2. The third red sub-pixel Pr3 may include the fifth light-emitting diode EDr3 and the fifth sub-pixel circuit PCr3 electrically connected to the fifth light-emitting diode EDr3.

The first light-emitting diode EDr1 may be disposed on the first slope surface ss1 of the first organic pattern 209p1. For example, the pixel electrode 310 of the first light-emitting diode EDr1 may extend from the upper surface 207us of the planarization layer 207 to the first upper surface us1 of the first organic pattern 209p1 through the first slope surface ss1 of the first organic pattern 209p1. The second light-emitting diode EDr2 may be disposed on the second slope surface ss2 of the first organic pattern 209p1. For example, the pixel electrode 310 of the second light-emitting diode EDr2 may extend from the upper surface 207us of the planarization layer 207 to the first upper surface us1 of the first organic pattern 209p1 through the second slope surface ss2 of the first organic pattern 209p1. The fifth light-emitting diode EDr3 may be disposed on the first upper surface us1 of the first organic pattern 209p1.

The first light-emitting diode EDr1 may be configured to emit light according to an electrical signal applied to the first sub-pixel circuit PCr1, the second light-emitting diode EDr2 may be configured to emit light according to an electrical signal applied to the second sub-pixel circuit PCr2, and the fifth light-emitting diode EDr3 may be configured to emit light according to an electrical signal applied to the fifth sub-pixel circuit PCr3. For example, the first light-emitting diode EDr1, the second light-emitting diode EDr2, and the fifth light-emitting diode EDr3 may be configured to emit light according to different electrical signals, and thus, emit light simultaneously or different timings.

The second organic pattern 209p2 may overlap the second sub-pixel group SG2. The second sub-pixel group SG2 may include the first blue sub-pixel Pb1, the second blue sub-pixel Pb2, and the third blue sub-pixel Pb3. The first blue sub-pixel Pb1 may include the third light-emitting diode EDb1 and the third sub-pixel circuit PCb1 electrically connected to the third light-emitting diode EDb1. The second blue sub-pixel Pb2 may include the fourth light-emitting diode EDb2 and the fourth sub-pixel circuit PCb2 electrically connected to the fourth light-emitting diode EDb2. The third blue sub-pixel Pb3 may include a sixth light-emitting diode EDb3 and a sixth sub-pixel circuit PCb3 electrically connected to the sixth light-emitting diode EDb3.

The third light-emitting diode EDb1 may be disposed on the third slope surface ss3 of the second organic pattern 209p2. For example, the pixel electrode 310 of the third light-emitting diode EDb1 may extend from the upper surface 207us of the planarization layer 207 to the second upper surface us2 of the second organic pattern 209p2 through the third slope surface ss3 of the second organic pattern 209p2. The fourth light-emitting diode EDb2 may be disposed on the fourth slope surface ss4 of the second organic pattern 209p2. The pixel electrode 310 of the fourth light-emitting diode EDb2 may extend from the upper surface 207us of the planarization layer 207 to the second upper surface us2 of the second organic pattern 209p2 through the fourth slope surface ss4 of the second organic pattern 209p2. The pixel electrode 310 of the sixth light-emitting diode EDb3 may be disposed on the second upper surface us2 of the second organic pattern 209p2.

The third light-emitting diode EDb1 may be configured to emit light according to an electrical signal applied to the third sub-pixel circuit PCb1, the fourth light-emitting diode EDb2 may be configured to emit light according to an electrical signal applied to the fourth sub-pixel circuit PCb2, and the sixth light-emitting diode EDb3 may be configured to emit light according to an electrical signal applied to the sixth sub-pixel circuit PCb3. That is, the third light-emitting diode EDb1, the fourth light-emitting diode EDb2, and the sixth light-emitting diode EDb3 may be configured to emit light according to different electrical signals, and thus, emit light simultaneously or at different timings.

The bank layer BNL may define the openings OP respectively overlapping the light-emitting didoes EDr1, EDr2, EDr3, EDb1, EDb2, and EDb3. The openings OP may expose the central portions of the pixel electrodes 310. The openings OP corresponding to the light-emitting didoes EDr1, EDr2, EDb1, and EDb2 may respectively overlap the first slope surface ss1, the second slope surface ss2, the third slope surface ss3, and the fourth slope surface ss4.

The first light-emitting diode EDr1, the second light-emitting diode EDr2, and the fifth light-emitting diode EDr3 may be configured to emit light of the same color. For example, the first light-emitting diode EDr1, the second light-emitting diode EDr2, and the fifth light-emitting diode EDr3 may be configured to emit red light. The third light-emitting diode EDb1, the fourth light-emitting diode EDb2, and the sixth light-emitting diode EDb3 may be configured to emit light of the same color. For example, the third light-emitting diode EDb1, the fourth light-emitting diode EDb2, and the sixth light-emitting diode EDb3 may be configured to emit blue light.

The openings OP of the bank layer BNL may be different in their sizes depending on emission efficiencies of the light-emitting diodes EDr1, EDr2, EDr3, EDb1, EDb2, and EDb3. Accordingly, the widths (or the areas) of the emission areas EA defined by the openings OP may be different from each other.

The encapsulation layer 400 encapsulating the light-emitting diodes EDr1, EDr2, EDr3, EDb1, EDb2, and EDb3 may be disposed on the display element layer 300. The encapsulation layer 400 may include at least one inorganic encapsulation layer and at least one organic encapsulation layer. It is shown in FIG. 11 that the encapsulation layer 400 may include the first inorganic encapsulation layer 410, the second inorganic encapsulation layer 430, and the organic encapsulation layer 420 disposed between the first inorganic encapsulation layer 410 and the second inorganic encapsulation layer 430.

The light-blocking layer 500 may be disposed on the encapsulation layer 400. The light-blocking layer 500 may include a light-blocking pattern 510 and an overcoat layer 520.

The light-blocking pattern 510 may be disposed on the second inorganic encapsulation layer 430. The light-blocking pattern 510 may include a light-absorption material and/or a low-reflective material. The light-blocking pattern 510 may define the light-transmissive openings 510OP overlapping the openings OP of the bank layer BNL. A body portion of the light-blocking pattern 510 may overlap a body portion of the bank layer BNL.

The body portion of the light-blocking pattern 510 may define a light-blocking area SHA blocking light emitted by the light-emitting diodes EDr1, EDr2, EDr3, EDb1, EDb2, and EDb3. The light-transmissive openings 510OP of the light-blocking pattern 510 may define a transmissive area TA through which light emitted by the light-emitting diodes EDr1, EDr2, EDr3, EDb1, EDb2, and EDb3 may pass. Because the light-transmissive openings 510OP of the light-blocking pattern 510 overlap the openings OP of the bank layer BNL, the transmissive areas TA may overlap the emission areas EA.

The overcoat layer 520 may be disposed on the light-blocking pattern 510 to cover the light-blocking pattern 510. The overcoat layer 520 may bury the light-transmissive openings 510OP of the light-blocking pattern 510 and provide a flat upper surface.

In an embodiment, the light-blocking pattern 510 may include a plurality of layers. For example, the light-blocking pattern 510 may include a first light-blocking pattern and a second light-blocking pattern. One or more light-transmissive material layer may be disposed between the first light-blocking pattern and the second light-blocking pattern.

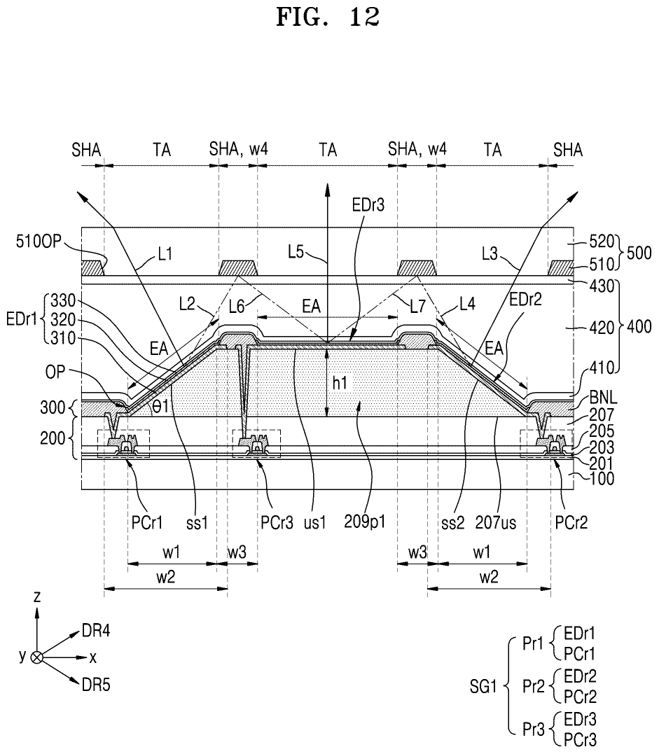

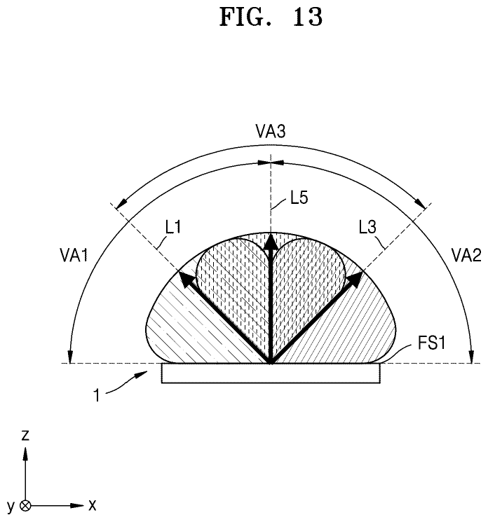

FIG. 12 is a view for explaining a path of light emitted by the display apparatus 1 according to an embodiment of the inventive concept, and FIG. 13 is a view for explaining a triple-view display apparatus according to an embodiment of the inventive concept.

Referring to FIG. 12, the display apparatus 1 may include the substrate 100. The pixel circuit layer 200 may be disposed on the substrate 100, wherein the pixel circuit layer 200 includes the first sub-pixel circuit PCr1, the second sub-pixel circuit PCr2, the buffer layer 201, the gate insulating layer 203, the interlayer insulating layer 205, and the planarization layer 207.

The first organic pattern 209p1 may be disposed on the pixel circuit layer 200. The first organic pattern 209p1 may have the first slope surface ss1, the second slope surface ss2, and the first upper surface us1. The first slope surface ss1 is inclined in the fourth direction DR4 oblique with respect to the upper surface of the substrate 100, the second slope surface ss2 is inclined in the fifth direction DR5 different from the fourth direction DR4, and the first upper surface us1 connects the first slope surface ss1 to the second slope surface ss2. The first slope surface ss1 and the second slope surface ss2 of the first organic pattern 209p1 may form the first angle θ1 with respect to the upper surface 207us of the planarization layer 207. The first upper surface us1 of the first organic pattern 209p1 may have the first height h1 measured along the third direction (z direction) from the upper surface 207us of the planarization layer 207. The first height h1 may be 10 μm or less.

The display element layer 300 may be disposed on the planarization layer 207 and the first organic pattern 209p1. The display element layer 300 may include the first light-emitting diode EDr1, the second light-emitting diode EDr2, the fifth light-emitting diode EDr3, and the bank layer BNL.

Each of the first light-emitting diode EDr1, the second light-emitting diode EDr2, and the fifth light-emitting diode EDr3 may include the pixel electrode 310, the opposite electrode 330, and the emission layer 320 disposed between the pixel electrode 310 and the opposite electrode 330.

The bank layer BNL may be disposed on the planarization layer 207 and the first organic pattern 209p1 to cover the edges of the pixel electrodes 310. The bank layer BNL may define the openings OP respectively exposing the upper surfaces of the pixel electrodes 310. The openings of the bank layer BNL may define an emission area EA of each sub-pixel P. In an embodiment, the first organic pattern 209p1 may include the same material as that of the bank layer BNL.

The first organic pattern 209p1 may overlap the first sub-pixel group SG1. The first sub-pixel group SG1 may include the first red sub-pixel Pr1, the second red sub-pixel Pr2, and the third red sub-pixel Pr3. The first red sub-pixel Pr1 may include the first light-emitting diode EDr1 and the first sub-pixel circuit PCr1 electrically connected to the first light-emitting diode EDr1. The second red sub-pixel Pr2 may include the second light-emitting diode EDr2 and the second sub-pixel circuit PCr2 electrically connected to the second light-emitting diode EDr2. The third red sub-pixel Pr3 may include the fifth light-emitting diode EDr3 and the fifth sub-pixel circuit PCr3 electrically connected to the fifth light-emitting diode EDr3. The first light-emitting diode EDr1, the second light-emitting diode EDr2, and the fifth light-emitting diode EDr3 may be configured to emit light of the same color.

The first light-emitting diode EDr1 may be disposed on the first slope surface ss1 of the first organic pattern 209p1. For example, the pixel electrode 310 of the first light-emitting diode EDr1 may extend from the upper surface 207us of the planarization layer 207 to the first upper surface us1 of the first organic pattern 209p1 through the first slope surface ss1 of the first organic pattern 209p1. The second light-emitting diode EDr2 may be disposed on the second slope surface ss2 of the first organic pattern 209p1. For example, the pixel electrode 310 of the second light-emitting diode EDr2 may extend from the upper surface 207us of the planarization layer 207 to the first upper surface us1 of the first organic pattern 209p1 through the second slope surface ss2 of the first organic pattern 209p1. The fifth light-emitting diode EDr3 may be disposed on the first upper surface us1 of the first organic pattern 209p1. For example, the pixel electrode 310 of the fifth light-emitting diode EDr3 may be disposed on the first upper surface us1 of the first organic pattern 209p1.

In a plan view, the first slope surface ss1 of the first organic pattern 209p1 may have a first width w1 measured along the first direction (x direction). In a plan view, the pixel electrode 310 of the first light-emitting diode EDr1 may have a second width w2 measured along the first direction (x direction). The first width w1 may be less than the second width w2.

Likewise, when viewed in a plane, the second slope surface ss2 of the first organic pattern 209p1 may have the first width w1 measured along the first direction (x direction) like the first slope surface ss1. Like the pixel electrode 310 of the first light-emitting diode EDr1, the pixel electrode 310 of the second light-emitting diode EDr2 may have the second width w2 measured along the first direction (x direction).

In this case, a contact portion may be disposed on the upper surface 207us of the planarization layer 207. The contact portion connects the pixel electrode 310 of the first light-emitting diode EDr1 to the first sub-pixel circuit PCr1. Likewise, a contact portion may be disposed on the upper surface 207us of the planarization layer 207, wherein the contact portion connects the pixel electrode 310 of the second light-emitting diode EDr2 to the second sub-pixel circuit PCr2. A contact portion may be disposed on the first upper surface us1 of the first organic pattern 209p1, wherein the contact portion connects the pixel electrode 310 of the fifth light-emitting diode EDr3 to the fifth sub-pixel circuit PCr3.

The first slope surface ss1 of the first organic pattern 209p1 forms the first angle θ1 counterclockwise with respect to the upper surface 207us of the planarization layer 207, and first light L1 emitted perpendicular to the pixel electrode 310 of the first light emitting diode EDr1 may proceed counterclockwise, oblique by the first angle θ1 with respect to the third direction (z direction) which is perpendicular to the upper surface of the substrate 100. The second slope surface ss2 of the first organic pattern 209p1 forms the first angle θ1 clockwise with respect to the upper surface 207us of the planarization layer 207, and third light L3 emitted perpendicular to the pixel electrode 310 of the second light emitting diode EDr2 may proceed clockwise, oblique by the first angle θ1 with respect to the third direction (z direction) which is perpendicular to the upper surface of the substrate 100. Fifth light L5 emitted perpendicular to the pixel electrode 310 of the fifth light-emitting diode EDr3 may proceed in the third direction (z direction) which is perpendicular to the upper surface of the substrate 100.

The body portion of the bank layer BNL may be disposed on the first upper surface us1 of the first organic pattern 209p1. The body portion of the bank layer BNL arranged between adjacent emission areas EA may have a third width w3.

The encapsulation layer 400 may be disposed on the display element layer 300, wherein the encapsulation layer 400 encapsulates the first light-emitting diode EDr1, the second light-emitting diode EDr2, and the fifth light-emitting diode EDr3.

The encapsulation layer 400 may include a first inorganic encapsulation layer 410, a second inorganic encapsulation layer 430, and an organic encapsulation layer 420 disposed between the first inorganic encapsulation layer 410 and the second inorganic encapsulation layer 430.

The light-blocking layer 500 may be disposed on the encapsulation layer 400. The light-blocking layer 500 may include the light-blocking pattern 510 and an overcoat layer 520. The light-blocking pattern 510 may define light-transmissive openings 510OP overlapping the openings OP of the bank layer BNL. A body portion of the light-blocking pattern 510 may overlap the body portion of the bank layer BNL. The body portion of the light-blocking pattern 510 may define the light-blocking area SHA. The light-transmissive openings 510OP of the light-blocking pattern 510 may define the transmissive area TA. The body portion of the light-blocking pattern 510 arranged between adjacent transmissive areas TA may have a fourth width w4 measured along the first direction (x direction).

The light-blocking pattern 510 may be configured to absorb a portion of light emitted by the light-emitting diodes EDr1, EDr2, and EDr3. The second light L2 emitted in a diagonal direction oblique to the right (+x direction) from the first light-emitting diode EDr1 may be absorbed by the body portion of the light-blocking pattern 510. The fourth light L4 emitted in a diagonal direction oblique to the left (−x direction) from the second light-emitting diode EDr2 may be absorbed by the body portion of the light-blocking pattern 510. The sixth light L6 emitted in a diagonal direction oblique to the left (−x direction) and seventh light L7 emitted in a diagonal direction oblique to the right (+x direction) from the fifth light-emitting diode EDr3 may be absorbed by the body portion of the light-blocking pattern 510. Accordingly, a viewing angle of light emitted from the light-emitting diodes EDr1, EDr2, and EDr3 may be determined by adjusting the third width w3 of the bank layer BNL and the fourth width w4 of the light-blocking pattern 510.

The overcoat layer 520 may be disposed on the light-blocking pattern 510 to cover the light-blocking pattern 510. The overcoat layer 520 may bury the light-transmissive openings 510OP of the light-blocking pattern 510 and provide a flat upper surface.

Referring to FIG. 13 and in conjunction with FIGS. 3 and 11, the display apparatus 1 may be configured to implement a triple view providing different images depending on a user's position. Light emitted by the first red sub-pixel Pr1 among the sub-pixels P in the first sub-pixel group SG1 may reach only the first view area VA1. Light emitted by the second red sub-pixel Pr2 among the sub-pixels P in the first sub-pixel group SG1 may reach only the second view area VA2. Light emitted by the third red sub-pixel Pr3 among the sub-pixels P in the third sub-pixel group SG3 may reach only a third view area VA3.

In this case, among light emitted by the first red sub-pixel Pr1, the first light L1 emitted perpendicular to the pixel electrode 310 of the first light-emitting diode EDr1 may have the strongest intensity. As described above, the direction of the first light L1 may be adjusted by the first angle θ1 which is an angle formed by the first slope surface ss1 of the first organic pattern 209p1 and the upper surface 207us of the planarization layer 207. Among light emitted by the first red sub-pixel Pr1, light emitted in a direction of the second view area VA2 may be absorbed by the light-blocking pattern 510.

Among light emitted by the second red sub-pixel Pr2, the third light L3 emitted perpendicular to the pixel electrode 310 of the second light-emitting diode EDr2 may have strongest intensity. The direction of the third light L3 may be adjusted by the first angle θ1 which is an angle formed by the second slope surface ss2 of the first organic pattern 209p1 and the upper surface 207us of the planarization layer 207. Among light emitted by the second red sub-pixel Pr2, light emitted in a direction of the first view area VA1 may be absorbed by the light-blocking pattern 510.

Among light emitted by the third red sub-pixel Pr3, the fifth light L5 emitted perpendicular to the pixel electrode 310 of the fifth light-emitting diode EDr3 may have strongest intensity. The fifth light L5 may proceed in a direction (e.g., z direction) perpendicular to the front surface FS1 of the display apparatus 1.

The third view area VA3 may overlap a portion of the first view area VA1 and a portion of the second view area VA2. When light travels in a direction close to a direction perpendicular to the pixel electrode 310 of each light-emitting diodes EDr1, EDr2, and EDr3, the light intensity is strong, whereas when light travels obliquely to the perpendicular direction, the light intensity is weaker. Thus, the impact of the light-emitting diodes EDr1, EDr2, and EDr3 on areas of the viewing area not corresponding with the pertinent light may be insignificant.

Accordingly, the display apparatus 1 may be configured to provide three different images to the first view area VA1, the second view area VA2, and the third view area VA3.

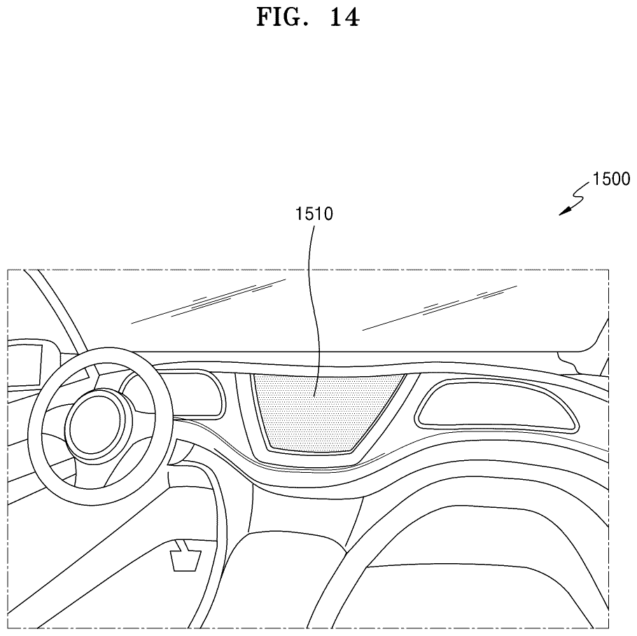

FIG. 14 is a schematic view of a vehicle including a display apparatus according to an embodiment of the inventive concept.

FIG. 14 shows a vehicle display apparatus 1500 as a display apparatus according to an embodiment. The vehicle display apparatus 1500 may include a center information display (CID) 1510. The CID 1510 is located between the driver's seat and the passenger seat, and may provide different images to a user located in the driver's seat, a passenger seat, and/or the back seat. For example, the CID 1510 may be configured to display navigation or vehicle operation information to the user located in the driver's seat while simultaneously displaying entertainment contents to the user located in the passenger seat and/or the back seat.

Although it is described in FIG. 14 that the CID 1510 is separated from a cluster display apparatus in front of the driver's seat and a display apparatus in front of the passenger seat, the embodiment is not necessarily limited thereto. The CID 1510 may extend and be integrally connected to the cluster display apparatus in front of the driver's seat and the display apparatus in front of the passenger seat.

According to an embodiment, a multi-view display apparatus configured to display different images depending on a user's position may be implemented. However, the scope of the disclosure is not limited by this effect.

Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as set forth by the following claims.

What is claimed is:

1. A display apparatus comprising:
a pixel circuit layer disposed on a substrate and including a plurality of sub-pixel circuits;
a planarization layer disposed on the pixel circuit layer;
a first organic pattern disposed on the planarization layer,
wherein the first organic pattern has a first slope surface inclined in a first direction, a second slope surface inclined in a second direction different from the first direction, and an upper surface connecting the first slope surface to the second slope surface;
a first light-emitting diode including a first pixel electrode extending from an upper surface of the planarization layer to the upper surface of the first organic pattern along the first slope surface; and
a second light-emitting diode including a second pixel electrode extending from the upper surface of the planarization layer to the upper surface of the first organic pattern along the second slope surface.

2. The display apparatus of claim 1, wherein the first light-emitting diode and the second light-emitting diode are configured to emit light of a same color.

3. The display apparatus of claim 2, wherein the first light-emitting diode and the second light-emitting diode are configured to emit light according to different electrical signals from each other.

4. The display apparatus of claim 1, further comprising a bank layer disposed on the planarization layer and defining openings that overlap with the first pixel electrode and the second pixel electrode respectively.

5. The display apparatus of claim 4, further comprising:
an encapsulation layer disposed on the first light-emitting diode and the second light-emitting diode; and
a light-blocking layer disposed on the encapsulation layer and defining light-transmissive openings overlapping the openings of the bank layer in a plan view.

6. The display apparatus of claim 1, wherein a first height in a thickness direction from the upper surface of the planarization layer to the upper surface of the first organic pattern is about 10 μm or less.

7. The display apparatus of claim 1,
wherein the first pixel electrode and the second pixel electrode are spaced apart from each other in a third direction parallel to an upper surface of the substrate,
wherein a width in the third direction of the first slope surface is less than a width in the third direction of the first pixel electrode, and
wherein a width in the third direction of the second slope surface is less than a width in the third direction of the second pixel electrode.

8. The display apparatus of claim 1, further comprising a third light-emitting diode including a third pixel electrode disposed on the upper surface of the first organic pattern.

9. The display apparatus of claim 8, wherein the first light-emitting diode, the second light-emitting diode, and the third light-emitting diode are configured to emit light of a same color as each other.

10. The display apparatus of claim 8, wherein the first light-emitting diode, the second light-emitting diode, and the third light-emitting diode are configured to emit light according to different electrical signals from each other.

11. A display apparatus comprising:
a pixel circuit layer disposed on a substrate and including a plurality of sub-pixel circuits;
a planarization layer disposed on the pixel circuit layer;
a first organic pattern disposed on the planarization layer,
wherein the first organic pattern has a first slope surface inclined in a first direction, a second slope surface inclined in a second direction different from the first direction, and an upper surface connecting the first slope surface to the second slope surface;
a second organic pattern which is disposed on the planarization layer, is spaced apart in a third direction from the first organic pattern,
wherein the second organic pattern has a third inclined surface inclined in the first direction, a fourth slope surface inclined in the second direction, and an upper surface connecting the third slope surface to the fourth slope surface;
a plurality of first sub-pixels overlapping the first organic pattern and configured to emit light of a first color; and
a plurality of second sub-pixels overlapping the second organic pattern and configured to emit light of a second color different from the first color.

12. The display apparatus of claim 11, wherein one of the plurality of first sub-pixels overlaps the first slope surface, another one of the plurality of first sub-pixels overlaps the second slope surface, one of the plurality of second sub-pixels overlaps the third slope surface, and another one of the plurality of second sub-pixels overlaps the fourth slope surface.

13. The display apparatus of claim 11, wherein one of the plurality of first sub-pixels overlaps the upper surface of the first organic pattern, and one of the plurality of second sub-pixels overlaps the upper surface of the second organic pattern.

14. The display apparatus of claim 11, wherein the plurality of first sub-pixels respectively include first light-emitting diodes, each including a first pixel electrode, an opposite electrode, and a first emission layer between the first pixel electrode and the opposite electrode,
wherein the plurality of second sub-pixels respectively include second light-emitting diodes, each including a second pixel electrode, the opposite electrode, and a second emission layer between the second pixel electrode and the opposite electrode,
wherein each of the first pixel electrodes extends from an upper surface of the planarization layer to the upper surface of the first organic pattern along the first slope surface or the second slope surface, and
wherein each of the second pixel electrodes extends from the upper surface of the planarization layer to the upper surface of the second organic pattern along the third slope surface or the fourth slope surface.

15. The display apparatus of claim 14, further comprising a bank layer disposed on the planarization layer,
wherein the bank layer defines openings that overlap with the first pixel electrodes and the second pixel electrodes respectively.

16. The display apparatus of claim 15, further comprising:
an encapsulation layer disposed on the first light-emitting diodes and the second light-emitting diodes; and
a light-blocking layer disposed on the encapsulation layer and defining light-transmissive openings overlapping the openings of the bank layer in a plan view.

17. The display apparatus of claim 11, wherein a first height in a thickness direction from an upper surface of the planarization layer to the upper surface of the first organic pattern is different from a second height in the thickness direction from the upper surface of the planarization layer to the upper surface of the second organic pattern.

18. The display apparatus of claim 11, wherein each of a first height in a thickness direction from an upper surface of the planarization layer to the upper surface of the first organic pattern and a second height in the thickness direction from the upper surface of the planarization layer and the upper surface of the second organic pattern are 10 μm or less.

19. The display apparatus of claim 11, further comprising:
a third organic pattern spaced apart from the first organic pattern and the second organic pattern; and
a plurality of third sub-pixels overlapping the third organic pattern and configured to emit light of a third color different from the first color and the second color.

20. The display apparatus of claim 11, wherein the plurality of first sub-pixels are spaced apart from each other in a third direction parallel to an upper surface of the substrate, the first organic pattern extends in a fourth direction crossing the third direction, and the display apparatus further includes a plurality of third sub-pixels overlapping the first organic pattern and spaced apart in the fourth direction from the plurality of first sub-pixels.
